(19) United States
(12) Patent Application Publication
(10) Pub. No.: US 2024/0365614 A1
(43) Pub. Date: Oct. 31, 2024

(54) DISPLAY PANEL

(71) Applicant: Samsung Display Co., Ltd., Yongin-si (KR)

(72) Inventors: KYUNGHOE LEE, Yongin-si (KR); SOIL YOON, Yongin-si (KR); CHEOL-GON LEE, Yongin-si (KR); MUKYUNG JEON, Yongin-si (KR)

(21) Appl. No.: 18/632,134

(22) Filed: Apr. 10, 2024

(30) Foreign Application Priority Data
Apr. 26, 2023 (KR) 10-2023-0054555

(51) Int. Cl. H10K 59/131; H10K 39/34; H10K 59/40

(52) U.S. Cl. CPC H10K 59/131; H10K 59/40; H10K 39/34

(57) ABSTRACT

A display panel includes a base layer, data lines extending in a first direction, arranged in a second direction crossing the first direction, pixels which are connected to the corresponding data lines and each of which includes an emission layer, lead-out lines extending in the first direction and between the data lines adjacent to each other, sensors which are connected to the corresponding lead-out lines, each of which includes a photoelectric conversion layer, and between the pixels adjacent to each other, and a sensor connection lines at one side and the other side of the base layer. Each of the sensor connection lines includes a first sensor pattern extending in the first direction and a second sensor pattern extending in the second direction to cross each of the data lines and the lead-out lines.

### CROSS-REFERENCE TO RELATED APPLICATION

The present application claims priority to and the benefit of Korean Patent Application No. 10-2023-0054555, filed on Apr. 26, 2023, the entire content of which is hereby incorporated by reference.

### BACKGROUND

Aspects of some embodiments of the present disclosure herein relate to a display panel capable of displaying images with relatively high brightness.

Multimedia display device such as televisions, mobile phones, tablet computers, navigators, game consoles, and the like generally include a display panel for displaying a relatively high-brightness image.

Such a display device may include an input sensor, which is capable of providing a touch-based input manner that allows a user to easily input information or commands intuitively and conveniently in addition to a usual input manners such as a button, a keyboard, a mouse, and the like.

The above information disclosed in this Background section is only for enhancement of understanding of the background and therefore the information discussed in this Background section does not necessarily constitute prior art.

### SUMMARY

Aspects of some embodiments of the present disclosure include a display device including a display panel capable of preventing or reducing a phenomenon in which resistance from increasing due to a bottleneck phenomenon of a power supply voltage on an area on which connection lines are densely arranged in a structure including a connection line located on an active area to reduce a peripheral area of the display panel.

According to some embodiments of the present disclosure, a display panel includes: a base layer including an active area and a peripheral area adjacent to the active area; data lines extending in a first direction, arranged in a second direction crossing the first direction, and on the base layer; pixels which are connected to the corresponding data lines and each of which includes an emission layer; lead-out lines extending in the first direction, between the data lines adjacent to each other, and on the base layer; sensors which are connected to the corresponding lead-out lines, each of which includes a photoelectric conversion layer, and between the pixels adjacent to each other; and a sensor connection line including first lead-out connection lines located at one side of the base layer and second lead-out connection lines located at the other side of the base layer based on a central axis extending in the first direction to cross a center of the base layer, the sensor connection line being connected to the corresponding lead-out lines, wherein each of the first lead-out connection lines and the second lead-out connection lines includes a first sensor pattern extending in the first direction and a second sensor pattern extending in the second direction to cross one of the data lines and the lead-out lines in a plan view.

According to some embodiments, the display panel may further include a mesh structure overlapping the active area and including first mesh lines extending in the first direction and second mesh lines on a layer which is different from a layer, on which the first mesh lines are located, and configured to define mesh openings, each of which surrounds the emission layer and the photoelectric conversion layer in the plan view, wherein the first mesh lines may be on the same layer as the first sensor patterns and spaced apart from the data lines, the lead-out lines, and the first sensor patterns, and the second mesh lines may be on the same layer as the second sensor patterns and spaced apart from the second sensor patterns.

According to some embodiments, one side of each of the second sensor patterns may be connected to the corresponding lead-out line, and the other side opposite to the one side in the second direction may be connected to the corresponding first sensor pattern.

According to some embodiments, the second sensor patterns may have the same width in the second direction, an area on which the second sensor patterns included in the first lead-out connection lines are located may have a first trapezoidal shape in the plan view, and an area on which the second sensor patterns included in the second lead-out connection lines are located may have a second trapezoidal shape in the plan view.

According to some embodiments, the first trapezoidal shape and the second trapezoidal shape may be symmetrical to each other with respect to the central axis.

According to some embodiments, the second trapezoidal shape may be shifted in the first direction compared to the first trapezoidal shape.

According to some embodiments, the second sensor patterns of the first lead-out connection lines aligned with each other in the second direction and the second mesh lines between the second sensor patterns of the second lead-out lines may have the same width in the second direction.

According to some embodiments, widths of the second sensor patterns of the first sensor connection patterns aligned with each other in the second direction and the second mesh lines between the second sensor patterns of the second sensor connection patterns in the second direction may be more than 5% of a width of the active area in the second direction.

According to some embodiments, widths of the second sensor patterns in the second direction may gradually increase from bottom to top of the active area, an area on which the second sensor patterns included in the first lead-out connection lines are located may have a first inverted triangular shape in the plan view, and an area on which the second sensor patterns included in the second lead-out connection lines are located may have a second inverted triangular shape in the plan view.

According to some embodiments, the second inverted triangular shape may be shifted in the first direction compared to the first inverted triangular shape.

According to some embodiments, the display panel may further include a signal line arranged along a boundary between the active area and the peripheral area and connected to the mesh structure.

According to some embodiments, the signal line may receive one of a driving voltage, an initialization voltage, and a reset voltage.

According to some embodiments, The display panel may further include a data connection line including first pixel connection lines at the one side of the base layer and second pixel connection lines at the other side of the base layer with respect to the central axis, the data connection line being connected to the corresponding data lines, wherein each of the first pixel connection lines and the second pixel connection lines may include a first pixel pattern extending in the first direction and a second pixel pattern extending in the second direction to cross one of the data lines and the lead-out lines in the plan view.

According to some embodiments, the mesh structure may be spaced apart from the data connection line.

According to some embodiments, widths of the second pixel patterns in the second direction may gradually increase from bottom to top of the active area, an area on which the second pixel patterns included in the first pixel connection lines are located may have a third inverted triangular shape in the plan view, and an area on which the second pixel patterns included in the second pixel connection lines are located may have a fourth inverted triangular shape in the plan view.

According to some embodiments, the third inverted triangular shape and the fourth inverted triangular shape may be symmetrical to each other with respect to the central axis.

According to some embodiments, the second sensor lines, the second pixel lines, and the second mesh lines may be on the same layer.

According to some embodiments, a portion of each of the lead-out lines, the data lines, the first sensor line, the first pixel lines, and the first mesh lines may be located on the same layer.

According to some embodiments, the display panel may further include a first pad part connected to the pixels and second pad parts connected to the sensors and spaced apart from each other in the second direction with the first pad part therebetween, wherein data lines connected to the data connection line among the data lines may be connected to the first pad part through the corresponding first pixel patterns, and remaining data lines may be directly connected to the first pad part, and lead-out lines connected to the sensor connection line among the lead-out lines may be connected to the corresponding second pad part through the first sensor patterns, and remaining lead-out lines may be directly connected to the corresponding second pad part.

According to some embodiments, each of the pixel may include a first electrode located below the emission layer, a first functional layer between the first electrode and the emission layer, a second electrode on the emission layer, and a second functional layer between the second electrode and the emission layer, and each of the sensors may include a first electrode below the photoelectric conversion layer, a first functional layer between the first electrode and the photoelectric conversion layer, a second electrode on the photoelectric conversion layer, and a second functional layer between the second electrode and the photoelectric conversion layer, wherein the first functional layer, the second functional layer, and the second electrode, which are included in each of the pixels and the sensors, may be provided as common layers.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to some embodiments of the present disclosure;

FIG. 2 is a block diagram of the display device according to some embodiments of the present disclosure;

FIG. 3 is a block diagram of a display panel and a display driving part according to some embodiments of the present disclosure;

FIG. 4 is a block diagram of an input sensor and a sensor driving part according to some embodiments of the present disclosure;

FIG. 5 is an equivalent circuit diagram of a pixel and a sensor according to some embodiments of the present disclosure;

FIG. 6 is a cross-sectional view of a display device according to some embodiments of the present disclosure;

FIG. 7A is a plan view of a display panel according to some embodiments of the present disclosure;

FIG. 7B is an enlarged plan view illustrating one area of the display panel according to some embodiments of the present disclosure;

FIG. 8 is a plan view of a display panel according to some embodiments of the present disclosure;

FIG. 9 is a plan view of a display panel according to some embodiments of the present disclosure;

FIG. 10 is a plan view of a display panel according to some embodiments of the present disclosure;

FIG. 11 is a plan view of a display panel according to some embodiments of the present disclosure;

FIG. 12 is a plan view of a display panel according to some embodiments of the present disclosure;

FIG. 13 is a plan view of a display panel according to some embodiments of the present disclosure;

FIG. 14 is a plan view of a display panel according to some embodiments of the present disclosure.

### DETAILED DESCRIPTION

In this specification, it will also be understood that when one component (or area, layer, portion) is referred to as being ‘on’, ‘connected to’, or ‘coupled to’ another component, it can be directly located/connected/coupled on/to the one component, or an intervening third component may also be present.

Like reference numerals refer to like elements throughout. Also, in the figures, the thickness, ratio, and dimensions of components are exaggerated for clarity of illustration. The term “and/or” includes any and all combinations of one or more of the associated elements.

It will be understood that although the terms such as ‘first’ and ‘second’ are used herein to describe various elements, these elements should not be limited by these terms. These terms are used only to distinguish one component from other components. For example, a first element referred to as a first element in some embodiments can be referred to as a second element in other embodiments without departing from the spirit and scope of the appended claims. The terms of a singular form may include plural forms unless referred to the contrary.

Also, “under”, “below”, “above’, “upper”, and the like are used for explaining relation association of the elements illustrated in the drawings. The terms may be a relative concept and described based on directions expressed in the drawings.

The meaning of ‘include’ or ‘comprise’ specifies a property, a fixed number, a process, an operation, an element, a component or a combination thereof, but does not exclude other properties, fixed numbers, processes, operations, elements, components or combinations thereof.

Unless otherwise defined, all terms (including technical and scientific terms) used herein have the same meaning as commonly understood by a person of ordinary skill in the art to which the present disclosure belongs. In addition, terms such as terms defined in commonly used dictionaries should be interpreted as having a meaning consistent with the meaning in the context of the related technology, and unless explicitly defined here, they are interpreted as too ideal or too formal sense.

Hereinafter, aspects of some embodiments of the present disclosure will be described in more detail with reference to the accompanying drawings.

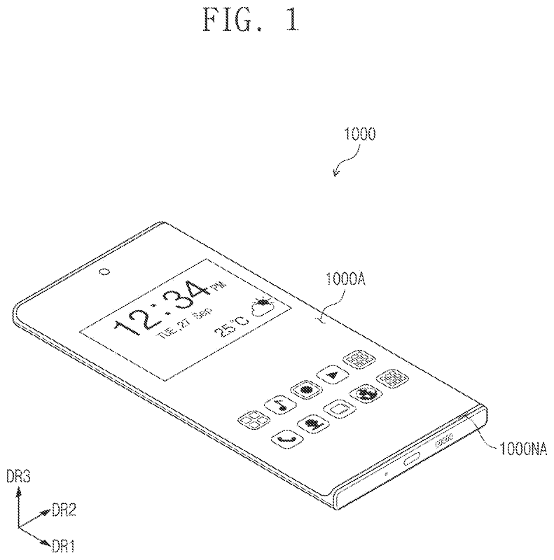

FIG. 1 is a perspective view of a display device 1000 according to some embodiments of the present disclosure.

Referring to FIG. 1, a display device 1000 may be a device activated according to an electrical signal. For example, the display device 1000 may be a mobile phone, a foldable mobile phone, a laptop computer, a television, a tablet, a car navigation system, a game console, or a wearable device, but embodiments according to the present disclosure are not limited thereto. FIG. 1 illustrates an example in which the display device 1000 is a mobile phone.

An active area 1000A and a peripheral area 1000NA may be defined on the display device 1000. The display device 1000 may display images at an active area 1000A. The active area 1000A may include a surface defined by a first direction DR1 and a second direction DR2. The peripheral area 1000NA may surround (e.g., in a periphery or outside a footprint of) the active area 1000A. The display device 1000 may display an image through the active area 1000A and sense an external input.

A thickness direction of the display device 1000 may be parallel to a third direction DR3 crossing the first direction DR1 and the second direction DR2. Thus, a front surface (or top surface) and a rear surface (or bottom surface) of each of members constituting the display device 1000 may be defined based on the third direction DR3.

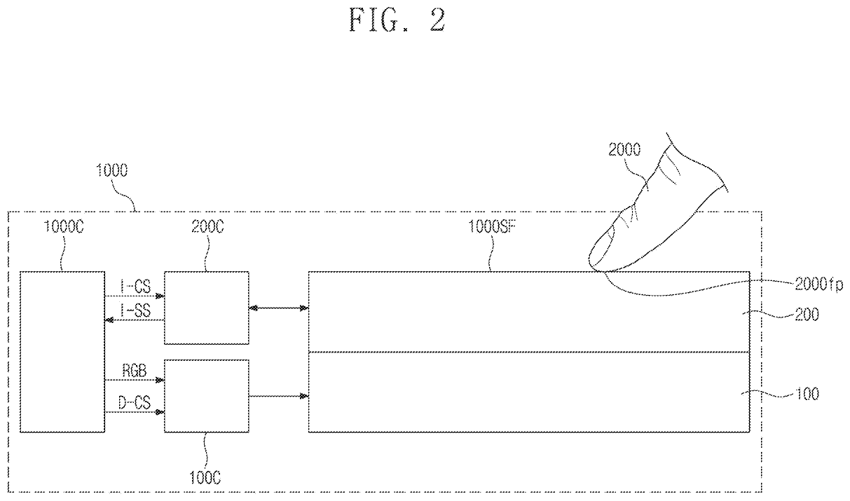

FIG. 2 is a block diagram of the display device 1000 according to some embodiments of the present disclosure.

Referring to FIG. 2, the display device 1000 may include a display panel 100, an input sensor 200, a display driving part 100C, a sensor driving part 200C, and a main driving part 1000C.

The display panel 100 may be configured to display images. The display panel 100 may be an emission type display panel. For example, the display panel 100 may include an organic light emitting display panel, an inorganic light emitting display panel, an organic-inorganic light emitting display panel, a quantum dot display panel, a micro LED display panel, or a nano LED display panel. In addition, the display panel 100 may include one or more sensors that sense or respond to light reflected by a user's fingerprint 2000fp.

The input sensor 200 may be located on the display panel 100. The input sensor 200 may sense an external input 2000 applied from the outside. The external input 2000 may include all input unit capable of providing a change in capacitance. For example, the input sensor 200 may sense an input by an active type input unit that provides a driving signal as well as a passive type input unit such as a user's body.

The main driving part 1000C may control an overall operation of the display device 1000. For example, the main driving part 1000C may control operations of the display driving part 100C and the sensor driving part 200C. The main driving part 1000C may include at least one microprocessor and may further include a graphic controller. The main driving part 1000C may be referred to as an application processor, a central processing unit, or a main processor.

The display driving part 100C may drive the display panel 100. The display driving part 100C may receive a image data RGB and a control signal D-CS from the main driving part 1000C. The control signal D-CS may include various signals. For example, the control signal D-CS may include an input vertical synchronization signal, an input horizontal synchronization signal, a main clock, and a data enable signal. The display driving part 100C may generate a vertical synchronization signal and a horizontal synchronization signal for controlling timing of providing a signal to the display panel 100 based on the control signal D-CS.

The sensor driving part 200C may drive the input sensor 200. The sensor driving part 200C may receive a control signal I-CS from the main driving part 1000C. The control signal I-CS may include a mode determination signal and a clock signal for determining a driving mode of the sensor driving part 200C.

The sensor driving part 200C may calculate input coordinate information based on the signal received from the input sensor 200 and provide a coordinate signal I-SS having the coordinate information to the main driving part 1000C. The main driving part 1000C executes an operation corresponding to a user input based on the coordinate signal I-SS. For example, the main driving part 1000C may operate the display driving part 100C to display a new application image on the display panel 100.

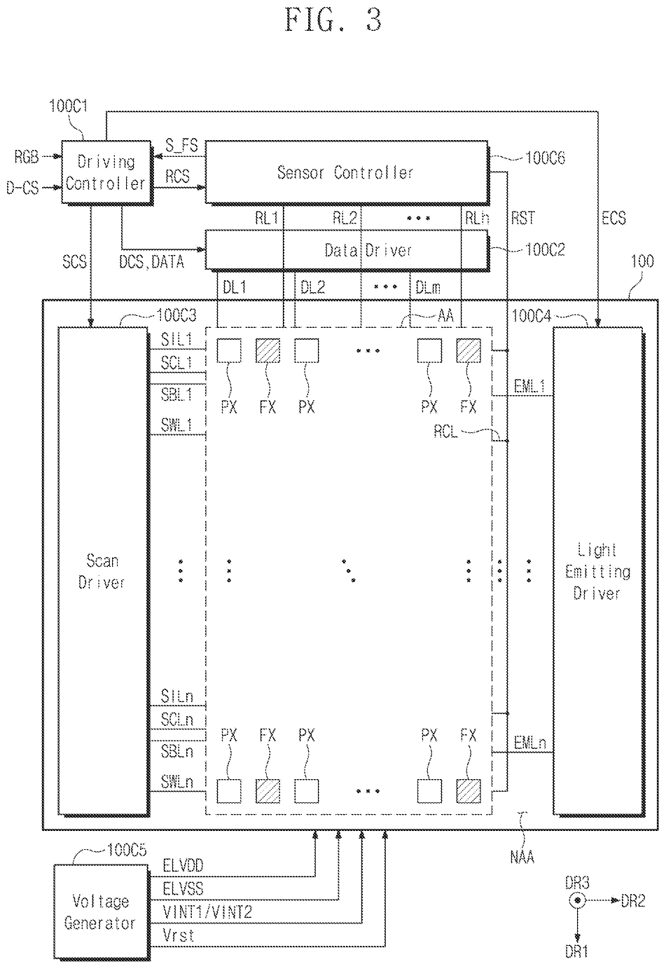

FIG. 3 is a block diagram of the display panel and the display driving part according to some embodiments of the present disclosure.

Referring to FIGS. 2 and 3, the display driving part 100C may include a driving controller 100C1, a data driver 100C2, a scan driver 100C3, a light emitting driver 100C4, a voltage generator 100C5, and a sensor controller 100C6.

The display panel 100 may include an active area AA corresponding to the active area 1000A see FIG. 1) and a peripheral area NAA corresponding to the peripheral area 1000NA (see FIG. 1).

The display panel 100 may include a plurality of pixels PX located on the active area AA and a plurality of sensors FX located on the active area AA. The display panel 100 may further include initialization scan lines SIL1 to SILn, compensation scan lines SCL1 to SCLn, write scan lines SWL1 to SWLn, black scan lines SBL1 to SBLn, emission control lines EML1 to EMLn, data lines DL1 to DLm, and lead-out lines RL1 to RLh.

The initialization scan lines SIL1 to SILn, the compensation scan lines SCL1 to SCLn, the write scan lines SWL1 to SWLn, the black scan lines SBL1 to SBLn, and the emission control lines EML1 to EMLn extend in the second direction DR2. The initialization scan lines SIL1 to SILn, the compensation scan lines SCL1 to SCLn, the write scan lines SWL1 to SWLn, the black scan lines SBL1 to SBLn, and the emission control lines EML1 to EMLn may be arranged to be spaced apart from each other in the first direction DR1.

The data lines DL1 to DLm and the lead-out lines RL1 to RLh extend in the first direction DR1 and are spaced apart from each other in the second direction DR2.

The plurality of pixels PX are electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DL1 to DLm, respectively. For example, each of the plurality of pixels PX may be electrically connected to four scan lines. However, the number of scan lines connected to each of the pixels PX is not limited thereto and may be changed.

The plurality of sensors FX are electrically connected to the lead-out lines RL1-RLh, respectively. One sensor FX may be electrically connected to one scan line, for example, one write scan line among the write scan lines SWL1 to SWLn. However, the embodiments of the present disclosure are not limited thereto. The number of scan lines connected to each of the sensors FX may vary.

The driving controller 100C1 receives the image data RGB and the control signal D-CS. The driving controller 100C1 generates an image data signal DATA that is obtained by converting data format of the image data RGB to meet interface specifications with the data driver 100C2. The driving controller 100C1 outputs a first control signal SCS, a second control signal ECS, a third control signal DCS, and a fourth control signal RCS.

The data driver 100C2 receives the third control signal DCS and the image data signal DATA from the driving controller 100C1. The data driver 100C2 converts the image data signal DATA into data signals and outputs the data signals to a plurality of data lines DL1 to DLm, which will be described in more detail later. The data signals are analog voltages corresponding to grayscale values of the image data signal DATA.

The scan driver 100C3 receives the first control signal SCS from the driving controller 100C1. The scan driver 100C3 may output scan signals to scan lines in response to the first control signal SCS. For example, the scan driver 100C3 outputs initialization scan signals to the initialization scan lines SIL1 to SILn and outputs compensation scan signals to the compensation scan lines SCL1 to SCLn in response to the first control signal SCS. In addition, the scan driver 100C3 may output write scan signals to the write scan lines SWL1 to SWLn and may output black scan signals to the black scan lines SBL1 to SBLn in response to the first control signal SCS.

The scan driver 100C3 may be located on the peripheral area NAA of the display panel 100. However, the embodiments of the present disclosure are not particularly limited thereto. For example, at least a portion of the scan driver 100C3 may be located on the active area AA.

The light emitting driver 100C4 may be located on the peripheral area NAA of the display panel 100. The light emitting driver 100C4 receives the second control signal ECS from the driving controller 100C1. The light emitting driver 4 may output emission control signals to the emission control lines EML1 to EMLn in response to the second control signal ECS. Alternatively, the scan driver 100C3 may be connected to the emission control lines EML1 to EMLn. In this case, the light emitting driver 100C4 may be omitted, and the scan driver 100C3 may output emission control signals to the emission control lines EML1 to EMLn.

The voltage generator 100C5 generates voltages that are necessary for the operation of the display panel 100. According to some embodiments, the voltage generator 100C5 generates a first driving voltage ELVDD, a second driving voltage ELVSS, a first initialization voltage VINT1, a second initialization voltage VINT2, and a reset voltage Vrst. According to some embodiments, a signal line providing the second driving voltage ELVSS may surround at least a portion of the active area AA so as to be adjacent to a boundary between the active area AA and the peripheral area NAA.

The sensor controller 100C6 receives the fourth control signal RCS from the driving controller 100C1. The sensor controller 100C6 may receive sensing signals from the lead-out lines RL1 to RLh in response to the fourth control signal RCS. The sensor controller 100C6 may process the sensing signals received from the lead-out lines RL1 to RLh and provide the processed sensing signals S_FS to the driving controller 100C1.

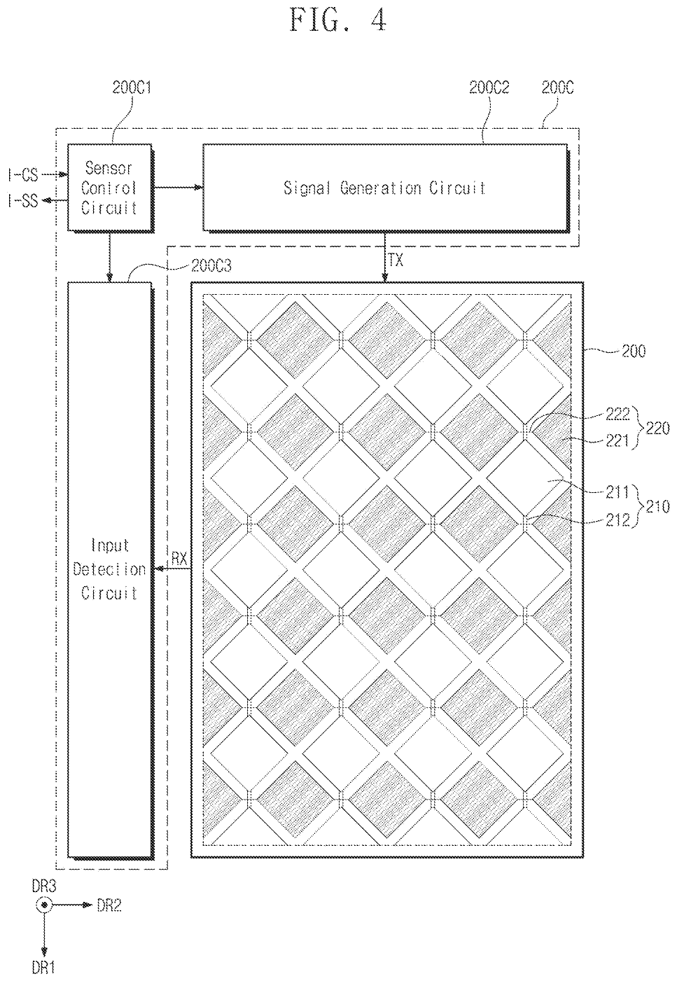

FIG. 4 is a block diagram of the input sensor and the sensor driving part according to some embodiments of the present disclosure.

Referring to FIG. 4, the input sensor 200 may include a plurality of first sensing electrodes 210 and a plurality of second sensing electrodes 220. Each of the plurality of second sensing electrodes 220 may cross the plurality of first sensing electrodes 210. According to some embodiments, the input sensor 200 may further include a plurality of signal lines connected to the plurality of first sensing electrodes 210 and the plurality of second sensing electrodes 220.

Each of the plurality of first sensing electrodes 210 may extend in the first direction DR1, and the plurality of first sensing electrodes 210 may be arranged to be spaced apart from each other in the second direction DR2. Each of the plurality of second sensing electrodes 220 may extend in the second direction DR2, and the plurality of second sensing electrodes 220 may be arranged to be spaced apart from each other in the first direction DR1.

Each of the plurality of first sensing electrodes 210 may include a sensing pattern 211 and a connection pattern 212. Two sensing patterns 211 adjacent to each other may be electrically connected to each other by two connection patterns 212, but the embodiments of the present disclosure are not particularly limited thereto. The sensing pattern 211 and the connection patterns 212 may be located on different layers.

Each of the plurality of second sensing electrodes 220 may include a first portion 221 and a second portion 222. The first portion 221 and the second portion 222 have shape integrated with each other and may be located on a same layer. For example, the first portion 221 and the second portion 222 may be located on same layer as the sensing pattern 211. The two connection patterns 212 may be insulated from and intersected with the second portion 222.

The sensor driving part 200C may receive the control signal I-CS from the main driving part 1000C (see FIG. 2). The sensor driving part 200C may provide the coordinate signal I-SS to the main driving part 1000C (see FIG. 2).

The sensor driving part 200C may be implemented as an integrated circuit (IC) and be directly mounted on an area (e.g., a set or predetermined area) of the input sensor 200 or mounted on a separate printed circuit board in a chip on film (COF) method so as to be electrically connected to the input sensor 200.

The sensor driving part 200C may include a sensor control circuit 200C1, a signal generation circuit 200C2, and an input detection circuit 200C3. The sensor control circuit 200C1 may control operations of the signal generation circuit 200C2 and the input detection circuit 200C3 based on the control signal I-CS.

The signal generation circuit 200C2 may output transmission signals TX to the first sensing electrodes 210 of the input sensor 200. The input detection circuit 200C3 may receive sensing signals RX from the input sensor 200. For example, the input detection circuit 200C3 may receive the sensing signals RX from the second sensing electrodes 220. According to some embodiments of the present disclosure, the signal generation circuit 200C2 may output the transmission signals TX to the second sensing electrodes 220 of the input sensor 200, and the input detection circuit 200C3 may receive the sensing signals RX from the first sensing electrodes 210.

Then, the input detection circuit 200C3 may convert an analog signal into a digital signal. For example, the input detection circuit 200C3 amplifies the received analog signal and then filters the amplified analog signal. That is, the input detection circuit 200C3 may convert the filtered signal into a digital signal.

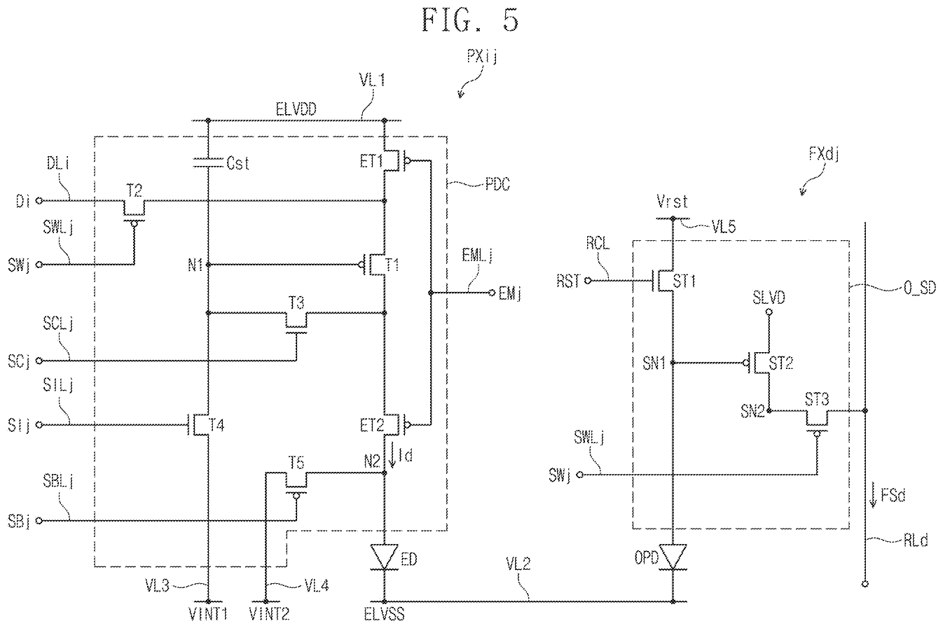

FIG. 5 is an equivalent circuit diagram of the pixel and the sensor according to some embodiments of the present disclosure.

FIG. 5 is an equivalent circuit diagram illustrating an example of one pixel PXij of the plurality of pixels PX (see FIG. 3). Because the plurality of pixels PX have the same circuit structure, detailed descriptions of other pixels PX will be omitted because of being substituting for the descriptions of the circuit structure of the pixel PXij. In addition, in FIG. 5, an equivalent circuit diagram of one sensor FXdj of the plurality of sensors FX illustrated in FIG. 3 is shown as an example. Because the plurality of sensors FX have the same circuit structure, a detailed description of other sensors FX will be omitted because of being substituting for the description of the circuit structure of the sensor FXdj.

Referring to FIGS. 3 and 5, the pixel PXij is connected to an i-th data line DLi of data lines DL1 to DLm, a j-th initialization scan line SILj of initialization scan lines SIL1 to SILn, a j-th compensation scan line SCLj of compensation scan lines SCL1 to SCLn, a j-th write scan line SWLj of write scan lines SWL1 to SWLn, a j-th black scan line SBLj of black scan lines SBL1 to SBLn, and a j-th emission control line EMLj of emission control lines EML1 to EMLn.

The pixel PXij includes a light emitting element ED and a pixel driving circuit PDC. The light emitting element ED may be an organic light emitting diode. As an example of the present disclosure, the light emitting element ED may be an organic light emitting diode including an organic light emitting layer, but it is not particularly limited thereto.

The pixel driving circuit PDC includes first to fifth transistors T1, T2, T3, T4, and T5, first and second emission control transistors ET1 and ET2, and one capacitor Cst.

At least one of the first to fifth transistors T1, T2, T3, T4, or T5 or the first and second emission control transistors ET1 and ET2 may be a transistor having a low-temperature polycrystalline silicon (LTPS) semiconductor layer. At least one of the first to fifth transistors T1, T2, T3, T4, or T5 or the first and second emission control transistors ET1 and ET2 may be a transistor having an oxide semiconductor layer. For example, the third and fourth transistors T3 and T4 may be oxide semiconductor transistors, the first, second, and fifth transistors T1, T2 and T5, and the first and second emission control transistors ET1 and ET2 may be LTPS transistors.

Particularly, the first transistor T1, which directly affects brightness of the display device 1000 (see FIG. 1), may be configured to include a highly reliable polycrystalline silicon semiconductor layer, through which a high-resolution display device is capable of being implemented. Because the oxide semiconductor has high carrier mobility and low leakage current, even if a driving time is long, voltage drop is not large. That is, because a color change of an image due to the voltage drop is not large even during low-frequency driving, low-frequency driving is possible. As described above, in the case of the oxide semiconductor, because the leakage current is small, at least one of the third transistor T3 or the fourth transistor T4 connected to the third electrode (or gate electrode) of the first transistor T1 may be employed as the oxide semiconductor to prevent or reduce instances of the leakage current flowing to the gate electrode and also relatively reduce power consumption.

Some of the first to fifth transistors T1, T2, T3, T4, and T5 and the first and second emission control transistors ET1 and ET2 may be P-type transistors, and others may be N-type transistors. For example, the first, second, and fifth transistors T1, T2, and T5 and the first and second emission control transistors ET1 and ET2 may be P-type transistors, and the third and fourth transistors T3 and T4 may be N-type transistors.

The configuration of the pixel driving circuit PDC according to the present disclosure is not limited to the embodiments illustrated in FIG. 5. The pixel driving circuit PDC illustrated in FIG. 5 is merely an example, and the configuration of the pixel driving circuit PDC may be modified to be implemented. For example, all of the first to fifth transistors T1, T2, T3, T4, and T5 and the first and second emission control transistors ET1 and ET2 may be P-type transistors or N-type transistors.

The j-th initialization scan line SILj, the j-th compensation scan line SCLj, the j-th write scan line SWLj, the j-th black scan line SBLj, and the j-th emission control line EMLj may transmit the j-th initialization scan signal Slj, the j-th compensation scan signal SCj, the j-th write scan signal SWj, the j-th black scan signal SBj, and the j-th emission control signal EMj to the pixel PXij, respectively. The i-th data line DLi may transmit an i-th data signal Di to the pixel PXij. The i-th data signal Di may have a voltage level corresponding to image data RGB (see FIG. 2) input to the display device 1000 (see FIG. 2).

The first and second driving voltage lines VL1 and VL2 may transmit a first driving voltage ELVDD and a second driving voltage ELVSS to the pixel PXij, respectively. In addition, the first and second initialization voltage lines VL3 and VL4 may transmit first and second initialization voltages VINT1 and VINT2 to the pixel PXij, respectively.

The first transistor T1 may be connected between the first driving voltage line VL1 receiving the first driving voltage ELVDD and the light emitting element ED. The first transistor T1 includes a first electrode connected to the first driving voltage line VL1 via a first emission control transistor ET1, a second electrode connected to the light emitting element ED via a second emission control transistor ET2, and a third electrode (e.g., gate electrode) connected to one end (e.g., first node B1) of the capacitor Cst. The first transistor T1 may receive the i-th data signal Di transmitted from the i-th data line DLi according to a switching operation of the second transistor T2 to supply driving current Id to the light emitting diode ED.

The second transistor T2 is connected between the data lien DLi and the first electrode of the first transistor T1. The second transistor T2 includes a first electrode connected to the data line DLi, a second electrode connected to the first electrode of the first transistor T1, and a third electrode (e.g., gate electrode) connected to a j-th write scan line SWLj. The second transistor T2 may be turned on according to the write scan signal SWj transmitted through the j-th write scan line SWLj to transmit the i-th data signal Di transmitted from the i-th data line DLi to the first electrode of the first transistor T1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (e.g., gate electrode) connected to the j-th compensation scan line SCLj. The third transistor T3 may be turned on according to the j-th compensation scan signal SCj transmitted through the j-th compensation scan line SCLj to connect the third electrode of the first transistor T1 to the second electrode, thereby diode-connecting the first transistor T1.

The fourth transistor T4 is connected between the first initialization voltage line VL3, to which the first initialization voltage VINT1 is applied, and the first node N1. The fourth transistor T4 includes a first electrode connected to the first initialization voltage line VL3, to which the first initialization voltage VINT is transmitted, a second electrode connected to the first node N1, and a third electrode (e.g., gate electrode) connected to the j-th initialization scan line SILj. The fourth transistor T4 is turned on according to the j-th initialization scan signal Slj transmitted through the j-th initialization scan line SILj. The turn-on fourth transistor T4 transmits the first initialization voltage VINT1 to the first node N1 to initialize a potential of the third electrode (i.e., potential of the first node N1) of the first transistor T1.

The first emission control transistor ET1 includes a first electrode connected to the first driving voltage line VL1, a second electrode connected to the first electrode of the first transistor T1, and a third electrode (e.g., gate electrode) connected to the j-th emission control line EMLj.

The second emission control transistor ET2 includes a first electrode connected to the second electrode of the first transistor T1, a second electrode connected to the light emitting element ED, and a third electrode (e.g., gate electrode) connected to the j-th emission control line EMLj.

The first and second emission control transistors ET1 and ET2 are simultaneously turned on according to the j-th emission control signal EMj transmitted through the j-th emission control line EMLj. The first driving voltage ELVDD applied through the turned-on first emission control transistor ET1 may be compensated through the diode-connected first transistor T1 and then transferred to the light emitting element ED.

The fifth transistor T5 includes a first electrode connected to the second initialization voltage line VL4, to which the second initialization voltage VINT2 is transmitted, a second electrode connected to the second electrode of the second emission control transistor ET2, and a third electrode (e.g., gate electrode) connected to the black scan line SBLj. The second initialization voltage VINT2 may have a voltage level equal to or less than that of the first initialization voltage VINT1.

As described above, one end of the capacitor Cst is connected to the third electrode of the first transistor T1, and the other end of the capacitor Cst is connected to the first driving voltage line VL1. The cathode of the light emitting element ED may be connected to the second driving voltage line VL2 that transmits the second driving voltage ELVSS. The second driving voltage ELVSS may have a voltage level less than that of the first driving voltage ELVDD.

The sensor FX is connected to a d-th lead-out line RLd of the lead-out lines RL1 to RLh, a j-th write scan line SWLj (or referred to as an output control line), and a reset control line RCL.

The sensor FX includes a light sensing element OPD (or referred to as a sensing element) and a sensor driving circuit O_SD.

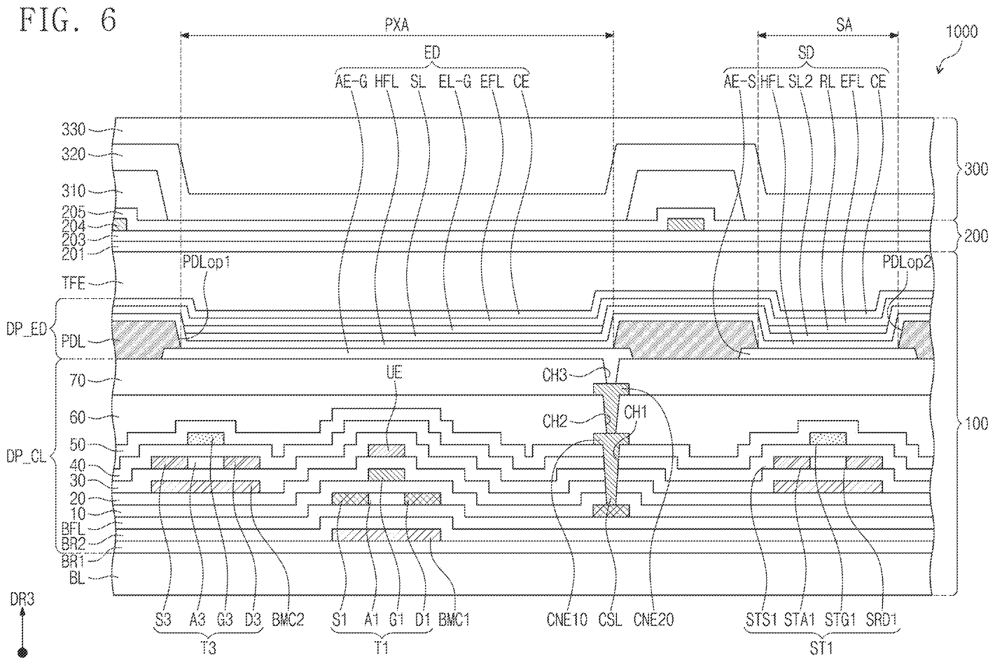

The light sensing element OPD may be a photodiode. As an example of the present disclosure, the light sensing element OPD may be an organic photodiode including an organic material as a photoelectric conversion layer. The first electrode AE-S (see FIG. 6) of the light sensing element OPD may be connected to the first sensing node SN1, and the second electrode CE (see FIG. 6) of the light sensing element OPD may be connected to the second driving voltage line VL2 that transmits the second driving voltage ELVSS. In FIG. 5, the sensor FX includes one light sensing element OPD as an example, but it is not particularly limited thereto. For example, the sensor FX may include z light sensing elements connected in parallel with each other. Reference symbol z may be an integer of 2 or greater.

The sensor driving circuit O_SD includes three transistors ST1, ST2, and ST3. The three transistors ST1, ST2, and ST3 may be a reset transistor ST1, an amplification transistor ST2, and an output transistor ST3, respectively. At least one of the reset transistor ST1, the amplification transistor ST2, or the output transistor ST3 may be an oxide semiconductor transistor. As an example of the present disclosure, the reset transistor ST1 may be an oxide semiconductor transistor, and the amplification transistor ST2 and the output transistor ST3 may be LTPS transistors. However, the embodiments of the present disclosure are not limited thereto, and at least the reset transistor ST1 and the output transistor ST3 may be oxide semiconductor transistors, and the amplification transistor ST2 may be an LTPS transistor.

In addition, some of the reset transistor ST1, the amplification transistor ST2, and the output transistor ST3 may be P-type transistors, and others may be N-type transistors. As an example of the present disclosure, the amplification transistor ST2 and the output transistor ST3 may be P-type transistors, and the reset transistor ST1 may be an N-type transistor. However, the embodiments of the present disclosure are not limited thereto, and all of the reset transistor ST1, the amplification transistor ST2, and the output transistor ST3 may be N-type transistors or be P-type transistors.

The circuit configuration of the sensor driving circuit O_SD according to the present disclosure is not limited to FIG. 5. The sensor driving circuit O_SD illustrated in FIG. 5 is merely an example, and the configuration of the sensor driving circuit O_CD may be modified to be implemented.

The reset transistor ST1 includes a first electrode connected to the third initialization voltage line VL5 to receive the reset voltage Vrst, a second electrode connected to the first sensing node SN1, and a third electrode that receives a reset control signal RST. The reset transistor ST1 may reset a potential of the first sensing node SN1 to the reset voltage Vrst in response to the reset control signal RST. The reset control signal RST may be a signal provided through the reset control line RCL.

The amplification transistor ST2 includes a first electrode receiving the sensing driving voltage SLVD, a second electrode connected to the second sensing node SN2, and a third electrode connected to the first sensing node SN1. The amplification transistor ST2 may be turned on according to the potential of the first sensing node SN1 to apply the sensing driving voltage SLVD to the second sensing node SN2. As an example of the present disclosure, the sensing driving voltage SLVD may be one of the first driving voltage ELVDD and the first and second initialization voltages VINT1 and VINT2.

When the sensing driving voltage SLVD is the first driving voltage ELVDD, the first electrode of the amplification transistor ST2 may be electrically connected to the first driving voltage line VL1. When the sensing driving voltage SLVD is the first initialization voltage VINT1, the first electrode of the amplification transistor ST2 may be electrically connected to the first initialization voltage line VL3, and when the sensing driving voltage SLVD is the second initialization voltage VINT2, the first electrode of the amplification transistor ST2 may be electrically connected to the second initialization voltage line VL4.

The output transistor ST3 includes a first electrode connected to the second sensing node SN2, a second electrode connected to the d-th lead-out line RLd, and a third electrode receiving an output control signal. The output transistor ST3 may transmit a sensing signal FSd to the d-th lead-out line RLd in response to the output control signal. The output control signal may be a j-th write scan signal SWj (or referred to as a j-th output control signal) supplied through the j-th write scan line SWLj. That is, the output transistor ST3 may receive the j-th write scan signal SWj supplied from the j-th write scan line SWLj as the output control signal.

A reset period may be defined as an activation period (i.e., a high level period) of the reset control line RCL. When the high level reset control signal RST is supplied through the reset control line RCL, the reset transistor ST1 is turned on. Alternatively, when the reset transistor ST1 is provided as a PMOS transistor, a low level reset control signal RST may be supplied to the reset control line RCL during a reset period. During the reset period, the first sensing node SN1 may be reset to a potential corresponding to the reset voltage Vrst. As an example of the present disclosure, the reset voltage Vrst may have a voltage level lower than the second driving voltage ELVSS.

The light sensing element OPD of the sensor FX may be exposed to light during aemission period of the light emitting device ED. The voltage of the first sensing node SN1 may be maintained to the reset voltage Vrst during the reset period, and then, as the light sensing element OPD is exposed to light, the voltage of the first sensing node SN1 may be gradually shifted to the second driving voltage ELVSS. The amplification transistor ST2 may be a source follower amplifier that generates source-drain current in proportion to an amount of charges of the first sensing node SN1 input to the third electrode.

During the output period, the j-th write scan signal SWj having the low level is supplied to the output transistor ST3 through the j-th write scan line SWLj. When the output transistor ST3 is turned on in response to the j-th write scan signal SWj having the low level, the sensing signal FSd corresponding to the current flowing through the amplification transistor ST2 may be output to the d-th lead-out line RLd.

FIG. 6 is a cross-sectional view of the display device according to some embodiments of the present disclosure.

Referring to FIG. 6, the display device 1000 according to some embodiments may include a display panel 100, an input sensor 200, and an anti-reflection layer 300.

The display panel 100 may include a base layer BL, a circuit layer DP_CL located on the base layer BL, an element layer DP_ED, and an encapsulation layer TFE.

At least one inorganic layer may be located on a top surface of the base layer BL. The inorganic layer may include at least one of oxide, titanium oxide, silicon oxide, silicon oxynitride, zirconium oxide, or hafnium oxide. The inorganic layer may be provided as a multilayer. The multi-layered inorganic layers may constitute barrier layers BR1 and BR2 and/or a buffer layer BFL to be described later. The barrier layers BR1 and BR2 and the buffer layer BFL may be selectively arranged.

The barrier layers BR1 and BR2 prevent or reduce instances of foreign substances or contaminants being introduced from the outside. The barrier layers BR1 and BR2 may include a silicon oxide layer and a silicon nitride layer. The above-described layers may be included in plurality, and silicon oxide layers and silicon nitride layers may be alternately laminated.

The barrier layers BR1 and BR2 may include a first barrier layer BR1 and a second barrier layer BR2. A first back metal layer BMC1 may be located between the first barrier layer BR1 and the second barrier layer BR2. According to some embodiments of the present disclosure, the first back metal layer BMC1 may be omitted.

The buffer layer BFL may be located on the barrier layers BR1 and BR2. The buffer layer BFL improves bonding force between the base layer BL and the semiconductor pattern and/or the conductive pattern. The buffer layer BFL may include a silicon oxide layer and a silicon nitride layer. The silicon oxide layer and the silicon nitride layer may be alternately laminated.

The first semiconductor pattern may be located on the buffer layer BFL. The first semiconductor pattern may include a silicon semiconductor. For example, the silicon semiconductor may include amorphous silicon, polycrystalline silicon, and the like. For example, the first semiconductor pattern may include low-temperature polysilicon.

FIG. 6 illustrates only a portion of the first semiconductor pattern located on the buffer layer BFL, and the other portion of the first semiconductor pattern may be further located on the other area. The first semiconductor pattern may be arranged at a specific interval over the pixels. The first semiconductor pattern may have different electrical properties depending on whether the first semiconductor pattern is doped. The first semiconductor pattern may include a first region having high conductivity and a second region having low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or may be doped at a concentration less than that of the first region.

The first region may have conductivity greater than that of the second region and may substantially serve as an electrode or a signal line. The second region may substantially correspond to an active area (or channel) of the transistor. That is to say, a portion of the semiconductor pattern may be an active area of the transistor, another portion may be a source or drain region of the transistor, and further another portion may be a connection electrode or a connection signal line.

A first electrode S1, an active area A1, and a second electrode D1 of the first transistor T1 are formed from the first semiconductor pattern. The first electrode S1 and the second electrode D1 of the first transistor T1 extend from the active area A1 in direction opposite to each other.

A portion of the connection signal line CSL formed from the first semiconductor pattern is illustrated. Although not separately shown, the connection signal line CSL may be connected to the second electrode of the fifth transistor T5 (see FIG. 5) on a plane (or in a plan view, i.e., when viewed from a direction perpendicular or normal with respect to a display surface of the display device 1000).

A first insulating layer 10 may be located on the buffer layer BFL. The first insulating layer 10 commonly overlaps the plurality of pixels PX to cover the first semiconductor pattern. The first insulating layer 10 may include an inorganic layer and/or an organic layer and have a single-layered or multilayered structure. The first insulation layer 10 may include at least one of aluminum oxide, titanium oxide, silicon oxide, silicon nitride, silicon oxynitride, zirconium oxide, or hafnium oxide.

According to some embodiments, the first insulation layer 10 may be a single-layered silicon oxide layer. The insulating layer of the circuit layer DP_CL, which will be described later, as well as the first insulating layer 10 may be an inorganic layer and/or an organic layer and may have a single-layered or a multilayered structure. The inorganic layer may include at least one of the above-described materials, but embodiments according to the present disclosure are not limited thereto.

A third electrode G1 of the first transistor T1 is located on the first insulating layer 10. The third electrode G1 may be a portion of a metal pattern. The third electrode G1 of the first transistor T1 overlaps the active area A1 of the first transistor T1. In a process of doping the first semiconductor pattern, the third electrode G1 of the first transistor T1 may function as a mask. The third electrode G1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), and the like, but it is not particularly limited thereto.

The second insulating layer 20 may be located on the first insulating layer 10 and may cover the third electrode G1 of the first transistor T1. The second insulating layer 20 may be an inorganic layer and/or an organic layer and have a single-layered or multilayered structure. The second insulating layer 20 may include at least one of silicon oxide, silicon nitride, or silicon oxynitride. According to some embodiments, the second insulating layer 20 may have a multilayer structure including a silicon oxide layer and a silicon nitride layer.

An upper electrode UE and the second back metal layer BMC2 may be located on the second insulating layer 20. The upper electrode UE may overlap the third electrode G1. The upper electrode UE may be a portion of the metal pattern. A portion of the third electrode G1 and the upper electrode UE overlapping the portion of the third electrode G1 may define the capacitor Cst (see FIG. 5). According to some embodiments of the present disclosure, the second insulating layer 20 may be replaced with an insulating pattern. In this case, the upper electrode UE may be located on the insulating pattern, and the upper electrode UE may serve as a mask for forming the insulating pattern from the second insulating layer 20.

The second back metal layer BMC2 may be arranged to correspond to a lower portion of the oxide thin film transistor, for example, the third transistor T3. The second back metal layer BMC2 may receive a constant voltage or signal.

The third insulating layer 30 may be located on the second insulating layer 20 and may cover the upper electrode UE and the second back metal layer BMC2. The third insulating layer 30 may has a single layer or multilayer structure. For example, the third insulating layer 30 may have a multilayer structure including a silicon oxide layer and a silicon nitride layer.

The second semiconductor pattern may be located on the third insulating layer 30. The second semiconductor pattern may include an oxide semiconductor. The oxide semiconductor may include a plurality of regions classified according to whether the metal oxide is reduced. A region in which the metal oxide is reduced (hereinafter, referred to as a reduction region) has conductivity higher than that of a region in which the metal oxide is not reduced (hereinafter, referred to as a non-reduction region). The reduction region substantially serves as a source/drain of a transistor or a signal line. The non-reduction region substantially corresponds to the active area (or semiconductor region or channel) of the transistor. In other words, a portion of the second semiconductor pattern may be an active area of the transistor, another portion may be a source/drain region of the transistor, and further another portion may be a signal transfer region.

A first electrode S3, an active area A3, and a second electrode D3 of the third transistor T3 are formed from the second semiconductor pattern. Each of the first electrode S3 and the second electrode D3 includes a metal reduced from the metal oxide semiconductor. The first electrode S3 and the second electrode D3 may extend from the active area A3 in direction opposite to each other.

A fourth insulating layer 40 may be located on the third insulating layer 30. The fourth insulating layer 40 commonly overlaps the plurality of pixels PX to cover the second semiconductor pattern. The fourth insulation layer 40 may include at least one of aluminum oxide, titanium oxide, silicon oxide, silicon nitride, silicon oxynitride, zirconium oxide, or hafnium oxide.

The third electrode G3 of the third transistor T3 is located on the fourth insulating layer 40. The third electrode G3 may be a portion of the metal pattern. The third electrode G3 of the third transistor T3 overlaps the active area A3 of the third transistor T3. In a process of reducing the second semiconductor pattern, the third electrode G3 may serve as a mask. According to some embodiments of the present disclosure, the fourth insulating layer 40 may be replaced with an insulating pattern.

A fifth insulating layer 50 may be located on the fourth insulating layer 40 and may cover the third electrode G3. The fifth insulating layer 50 may be an inorganic layer.

A first connection electrode CNE10 may be located on the fifth insulating layer 50. The first connection electrode CNE10 may be connected to the connection signal line CSL through a first contact hole CH1 passing through the first to fifth insulating layers 10, 20, 30, 40, and 50.

A sixth insulating layer 60 may be located on the fifth insulating layer 50. The sixth insulating layer 60 may be an organic layer. The organic layer may include general-purpose polymers such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide polymer, an aryl ether polymer, an amide polymer, a fluorine polymer, a p-xylene polymer, a vinyl alcohol polymer, and a blend thereof.

A second connection electrode CNE20 may be located on the sixth insulating layer 60. The second connection electrode CNE20 may be connected to the first connection electrode CNE10 through a second contact hole CH2 passing through the sixth insulating layer 60. A seventh insulating layer 70 may be located on the sixth insulating layer 60 and may cover the second connection electrode CNE2. The seventh insulating layer 70 may be an organic layer.

The circuit layer DP_CL may further include a sensor driving circuit O_SD (see FIG. 5). For convenience of explanation, the reset transistor ST1 of the sensor driving circuit O_SD is illustrated. A first electrode STS1, an active area STA1, and a second electrode STD1 of the reset transistor ST1 are formed from the second semiconductor pattern. Each of the first electrode STS1 and the second electrode STD1 includes metal reduced from a metal oxide semiconductor. The fourth insulating layer 40 is arranged to cover the first electrode STS1, the active area STA1, and the second electrode STD1 of the reset transistor ST1. The third electrode STG1 of the reset transistor ST1 is located on the fourth insulating layer 40. According to some embodiments, the third electrode STG1 may be a portion of the metal pattern. The third electrode STG1 of the reset transistor ST1 overlaps the active area STA1 of the reset transistor ST1.

As an example of the present disclosure, the reset transistor ST1 may be located on the same layer as the third transistor T3. That is, the first electrode STS1, the active area STA1, and the second electrode STD1 of the reset transistor ST1 may be formed through the same process as that of forming the first electrode S3, the active area A3, and the second electrode D3 of the third transistor T3. The third electrode STG1 of the reset transistor ST1 may be simultaneously formed through the same process as that of forming the third electrode G3 of the third transistor T3. Although not separately shown, the amplification transistor ST2 of the sensor driving circuit O_SD and the first electrode and the second electrode of and output transistor ST3 may be formed through the same process as that of forming the first electrode S1 and the second electrode D1 of the first transistor T1. Because the reset transistor ST1 and the third transistor T3 are formed on the same layer through the same process, an additional process of forming the reset transistor ST1 may not be required to reduce process efficiency and costs.

An element layer DP_ED may be located on the circuit layer DP_CL. The element layer DP_ED may include light emitting elements ED and light sensing elements OPD. The light emitting elements ED may include first to third light emitting elements that generate light having different colors.

An emission area PXA may be defined to correspond to each of the light emitting elements ED, and a sensing area SA may be defined to correspond to the light sensing element OPD. Each of the emission area PXA and the sensing area SA may be defined by a pixel defining layer PDL, which will be described later.

Each of the light emitting elements ED may include first electrodes AE-G, a first functional layer HFL, emission layers EL, a second functional layer EFL, and a second electrode CE. The light sensing element OPD may include a first electrode AE-S, a first functional layer HFL, a photoelectric conversion layer RL, a second functional layer EFL, and a second electrode CE. The first functional layer HFL, the second functional layer EFL, and the second electrode CE may be a common layer that is commonly provided to the pixels PX (see FIG. 3) and the sensors FX (see FIG. 3).

A first electrode AE-G of the light emitting device ED and a first electrode AE-S of the light sensing element OPD are located on the seventh insulating layer 70. The first electrode AE-G of the light emitting element ED may be connected to the second connection electrode CNE20 through a third contact hole CH3 penetrating the seventh insulating layer 70.

The light emitting elements ED may further include an auxiliary layer SL2. The light emitting elements ED may further include additional auxiliary layers in addition to the auxiliary layer SL2. The auxiliary layer SL2 according to some embodiments may be commonly arranged in the emission area PXA and the sensing area SA. The additional auxiliary layers may not overlap the sensing area SA. The auxiliary layer SL may be located between the functional layer HFL and the emission layer EL and between the first functional layer HFL and the photoelectric conversion layer RL. The auxiliary layer SL2 may be provided to control a resonance distance. Thus, the auxiliary layer SL2 and the additional auxiliary layers may have different thicknesses.

The pixel defining layer PDL may be located on the seventh insulating layer 70 and may cover portions of each of the first electrodes AE-G and AE-S. Openings PDLop1 and PDLop2 are included in the pixel defining layer PDL. A plurality of emission areas PXA and a plurality of sensing areas SA may be defined by the openings PDLop1 and PDLop2.

For example, the emission area PXA may be defined by the first opening PDLop1, and the sensing area SA may be defined by the second opening PDLop2. The first opening PDLop1 may expose at least a portion of the first electrode AE-G of the light emitting device ED, and the second opening PDLop2 may expose at least a portion of the first electrode AE-S of the light sensing element OPD.

According to some embodiments of the present disclosure, the pixel defining layer PDL may further include a black material. The pixel defining layer PDL may further include a black organic dye/pigment such as carbon black or aniline black. The pixel defining layer PDL may be formed by mixing a blue organic material and a black organic material. The pixel defining layer PDL may further include a liquid repellent organic material.

The emission layer EL of the light emitting element ED may be located on an area corresponding to the first opening PDLop1. The emission layer EL may generate light having a color (e.g., a set or predetermined color). Although the patterned emission layer EL has been described as an example according to some embodiments, one emission layer may be commonly located on the plurality of emission areas. In this case, the emission layer may generate white light or blue light. In addition, the emission layer may have a multilayer structure referred to as a tandem.

The emission layer EL may include a small molecular organic material or a polymeric organic material as the light emitting material. Alternatively, the emission layer EL may include a quantum dot material as the light emitting material. A core of the quantum dot may be selected from Group II-VI compounds, Group III-V compounds, Group IV-VI compounds, Group IV elements, Group IV compounds, and a combination thereof.

The photoelectric conversion layer RL may be located on an area corresponding to the second opening PDLop2. The photoelectric conversion layer RL may include an organic photo sensing material. The second electrode CE may be located on the photoelectric conversion layer RL. Each of the first electrode AE-S and the second electrode CE may receive an electrical signal. The first electrode AE-S and the second electrode CE may receive signals different from each other. Thus, an electric field (e.g., a set or predetermined electric field) may be generated between the first electrode AE-S and the second electrode CE. The photoelectric conversion layer RL generates an electrical signal corresponding to light incident on the sensor.

Charges generated in the photoelectric conversion layer RL change the electric field between the first electrode AE-S and the second electrode CE. The amount of charges generated in the photoelectric conversion layer RL may vary depending on whether light is incident on the light sensing element OPD and an amount and intensity of light incident on the light sensing element OPD. Thus, the electric field generated between the first electrode AE-S and the second electrode CE may vary. The light sensing element OPD according to the present disclosure may obtain fingerprint information of the user through a change in electric field between the first electrode AE-S and the second electrode CE.

The encapsulation layer TFE is located on the element layer DP_ED. The encapsulation layer TFE includes at least an inorganic layer or organic layer. According to some embodiments of the present disclosure, the encapsulation layer TFE may include two inorganic layers and an organic layer located between the inorganic layers. According to some embodiments of the present disclosure, the thin film encapsulation layer may include a plurality of inorganic layers and a plurality of organic layers, which are alternately laminated.

The encapsulating inorganic layer protects the light emitting device ED and the light sensing element OPD from moisture/oxygen, and the encapsulation organic layer protects the light emitting device ED and the light sensing element OPD from foreign substances such as dust particles. The encapsulation inorganic film may include a silicon nitride layer, a silicon oxy nitride layer, a silicon oxide layer, a titanium oxide layer, or an aluminum oxide layer, but it is not limited thereto. The encapsulation organic layer may include an acrylic-based organic layer, but it is not specifically limited thereto.

The display device 1000 (see FIG. 1) may further include an input sensor 200 and an anti-reflection layer 300.

The input sensor 200 may be located on the display panel 100. The input sensor 200 may sense an external input applied from the outside. The external input may be a user's input. The user's input may include various types of external inputs such as a portion of user's body, light, heat, a pen, a pressure, or the like. The input sensor 200 may be referred to as a sensor, an input sensing layer, or an input sensing panel. The input sensor 200 may include a sensor base layer 201, a first sensor conductive layer 202, a sensor insulating layer 203, a second sensor conductive layer 204, and a sensor cover layer 205.

The sensor base layer 201 may be directly located on the display panel 100. The sensor base layer 201 may be an inorganic layer containing at least one of silicon nitride, silicon oxynitride, or silicon oxide. Alternatively, the sensor base layer 201 may be an organic layer including an epoxy resin, an acrylic resin, or an imide-based resin. Each of the sensor base layer 201 may have a single-layered structure or a multilayered structure in which a plurality of layers are laminated in the third direction DR3.

Each of the first sensor conductive layer 202 and the second sensor conductive layer 204 may have a single-layered structure or a multilayered structure in which a plurality of layers are laminated in the third directional axis DR3.

The conductive layer having the single-layered structure may include a metal layer or a transparent conductive layer. The metal layer may include molybdenum, silver, titanium, copper, aluminum, or an alloy thereof. The transparent conductive layer may include a transparent conductive oxide such as indium tin oxide, indium zinc oxide, zinc oxide, or indium zinc tin oxide. In addition, the transparent conductive layer may include conductive polymers such as PEDOT, metal nanowires, graphene, and the like.

The conductive layer having the multilayered structure may include metal layers. The metal layers may have a three-layered structure of titanium/aluminum/titanium. The conductive layer having the multilayered structure may include at least one metal layer and at least one transparent conductive layer.

The sensor insulating layer 203 may be located between the first sensor conductive layer 202 and the second sensor conductive layer 204. The sensor insulating layer 203 may include an inorganic layer. The inorganic layer may include at least one of oxide, titanium oxide, silicon oxide, silicon nitride, silicon oxynitride, zirconium oxide, or hafnium oxide

Alternatively, the sensor insulating layer 203 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The sensor cover layer 205 may be located on the sensor insulating layer 203 and may cover the second sensor conductive layer 204. The second sensor conductive layer 204 may include a conductive pattern. The sensor cover layer 205 may cover the conductive pattern and may reduce or eliminate probability of damage to the conductive pattern in a subsequent process. The sensor cover layer 205 may include an inorganic material. For example, the sensor cover layer 205 may include silicon nitride, but it is not particularly limited thereto. According to some embodiments of the present disclosure, the sensor cover layer 205 may be omitted.

The anti-reflection layer 300 may be located on the input sensor 200. The anti-reflection layer 300 may include a division layer 310, a plurality of color filters 320, and a planarization layer 330.

The division layer 310 may be arranged to overlap the conductive pattern of the second sensor conductive layer 204. The sensor cover layer 205 may be located between the division layer 310 and the second sensor conductive layer 204. The division layer 310 may prevent or reduce instances of external light being reflected by the second sensor conductive layer 204. A material forming the division layer 310 is not particularly limited as long as it is a material that absorbs light. The division layer 310 may be a layer having a black color, and according to some embodiments, the division layer 310 may include a black coloring agent. A black component may include a black dye and a black pigment. The black component may include a carbon black, a metal such as chromium, or oxide thereof.

A plurality of division openings may be defined in the division layer 310. The plurality of division openings may overlap emission layers EL-R, EL-G, and EL-B and the photoelectric conversion layer RL, respectively. The color filters 320 may be arranged to correspond to the plurality of division openings. The color filter 320 may transmit light provided from the emission layers EL-R, EL-G, and EL-B overlapping itself. Alternatively, light may be transmitted through the color filter 320 and provided to the photoelectric conversion layer RL.

FIG. 6 illustrates that one color filter 320 is commonly provided to the emission layer EL-G and the photoelectric conversion layer RL as an example. However, the embodiments of the present disclosure are not particularly limited thereto. For example, a color filter having a color different from that of the green color filter may be located on the photoelectric conversion layer RL. Alternatively, the color filter 320 may not be located on the photoelectric conversion layer RL.

The planarization layer 330 may cover the division layer 310 and the color filters 320. The planarization layer 330 may include an organic material and may provide a flat surface on a top surface of the planarization layer 330. According to some embodiments, the planarization layer 330 may be omitted.

According to some embodiments of the present disclosure, the anti-reflection layer 300 may include a reflection control layer instead of the color filters 320. For example, in FIG. 6, the color filters 320 may be omitted, and the reflection control layer may be added on a place on which the color filters 320 are omitted. The reflection control layer may selectively absorb light in a partial band among light reflected from the inside of the display panel and/or electronic device or light incident from the outside of the display panel and/or electronic device.

The display device 1000 according to some embodiments may further include a window located on the anti-reflection layer 300. The window may protect the display panel 100 and the input sensor 200 from external scratches. The window may have an optically transparent property. The window may include glass. However, the embodiments of the present disclosure are not limited thereto, and the window may include a synthetic resin film.

The window may have a multilayer structure or a single layer structure. For example, the window may include a plurality of plastic films bonded to each other by using an adhesive or include a glass substrate and a plastic film, which are bonded to each other by using an adhesive. The anti-reflection layer 300 and the window may be coupled to each other by an adhesive layer located therebetween. The adhesive layer may include a pressure sensitive adhesive (PSA) or an optically clear adhesive (OCA), but the type of adhesive is not limited thereto.

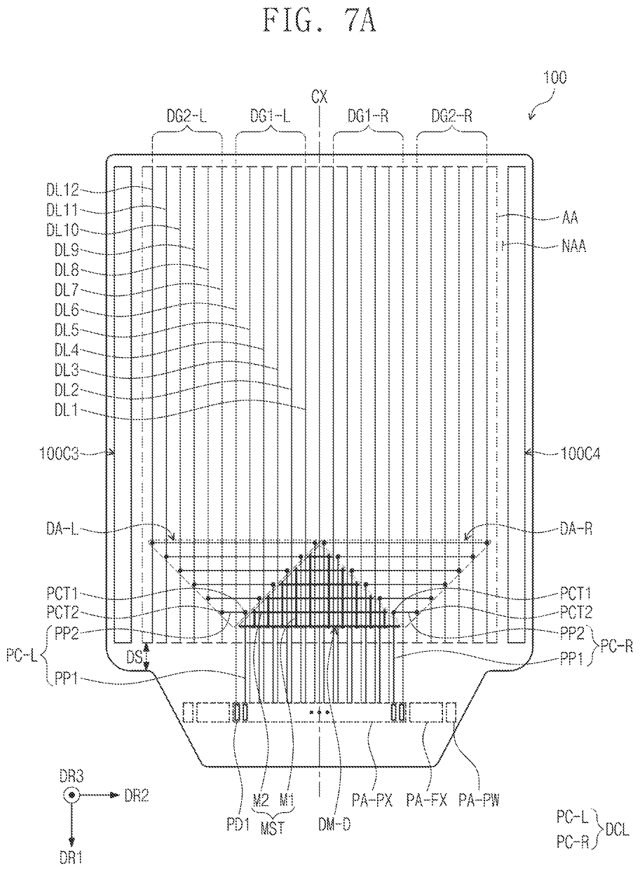

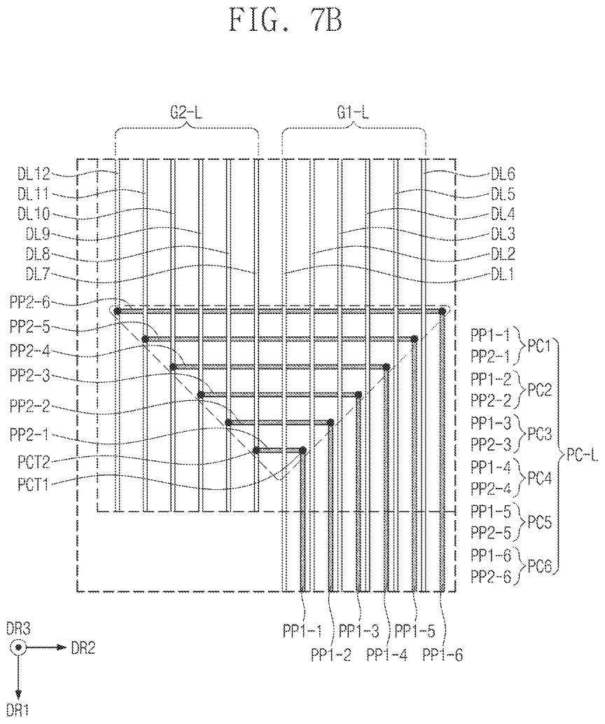

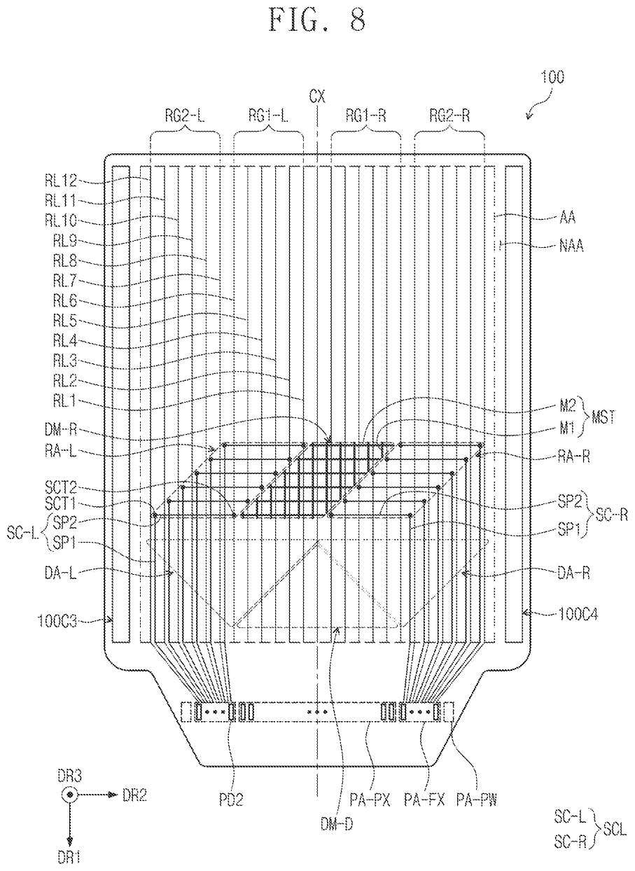

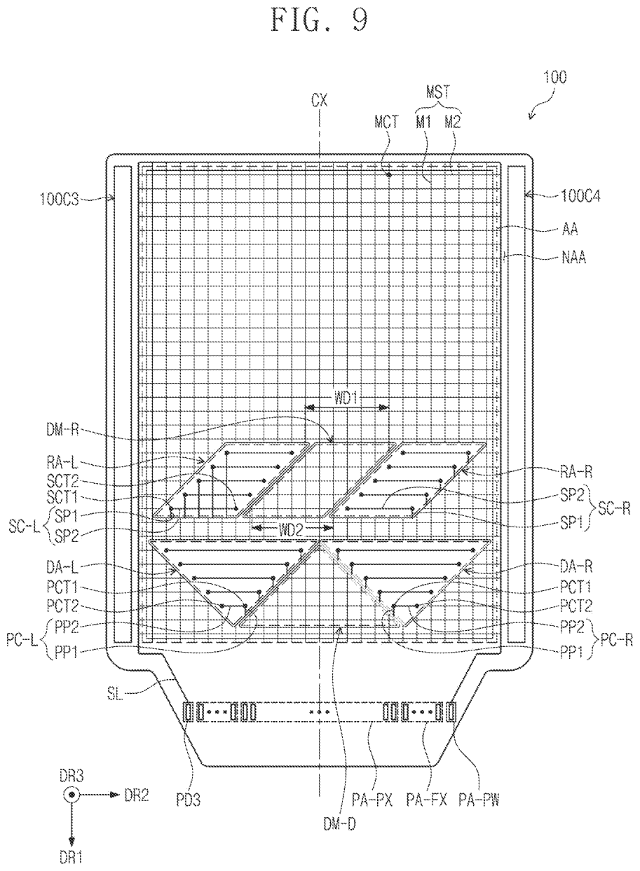

FIG. 7A is a plan view of the display panel according to some embodiments of the present disclosure. FIG. 7B is an enlarged plan view illustrating one area of the display panel according to some embodiments of the present disclosure. FIG. 8 is a plan view of the display panel according to some embodiments of the present disclosure. FIG. 9 is a plan view of a display panel according to some embodiments of the present disclosure.

FIGS. 7A, 8, and 9 illustrate only some of lines included in the display panel 100. FIG. 7A illustrates data lines and a data connection line, and FIG. 8 illustrates lead-out lines and a sensor connection line. FIG. 9 illustrates a mesh structure.

Referring to FIG. 7A, the display panel 100 may include data lines DL1 to DL12 connected to corresponding pixels PX (see FIG. 3) and data connection lines DCL connected to corresponding data lines DL1 to DL12. The data connection line DCL may include first pixel connection lines PC-L and second pixel connection lines PC-R.

In this specification, for convenience of explanation, the data lines DL1 to DL12 located at one side (left side) of the active area AA and data lines DL1 to DL12 located at the other side (right side) based on a central axis CX that crosses a center of the active area AA and extends in the first direction DR1 will be separately described.

The data lines DL1 to DL12 located at one side (left side) and the other side (right side) may be located on the same layer as the second connection electrode CNE20 described in FIG. 3. Each of the data lines DL1 to DL12 may extend in the first direction DR1 and may be arranged in the second direction DR2.

The data lines DL1 to DL12 located at one side of the active area AA may be divided into a first left group DG1-L and a second left group DG2-L. The data lines DL1 to DL6 included in the first left group DG1-L may be directly connected to a first pad area PA-PX defined on the peripheral area NAA. In more detail, The data lines DL1 to DL6 included in the first left group DG1-L may be directly connected to a corresponding pad of the first pads PD1 provided on the first pad area PA-PX.

The data lines DL7 to DL12 included in the second left group DG2-L may be connected to a corresponding pad of the first pads PD1 through the first pixel connection lines PC-L of the data connection lines DCL.

The data lines DL1 to DL12 located at the other side of the active area AA may be divided into a first right group DG1-R and a second right group DG2-R. The data lines DL1 to DL6 included in the first right group DG1-R may be directly connected to the first pad area PA-PX defined on the peripheral area NAA. In more detail, The data lines DL1 to DL6 included in the first left group DG1-L may be directly connected to a corresponding pad of the first pads PD1 provided on the first pad area PA-PX.

The data lines DL7 to DL12 included in the second right group DG2-R may be connected to the first pads PD1 through the second pixel connection lines PC-R of the data connection lines DCL.

According to some embodiments, each of the first pixel connection lines PC-L and the second pixel connection lines PC-R may include a first pixel pattern PP1 and a second pixel pattern PP2 connected to the first pixel pattern PP1. Each of the first pixel patterns PP1 may extend in the first direction DR1 and be located between the corresponding data lines of the data lines included in the first left group DG1-L and the first right group DG1-R.

Each of the second pixel patterns PP2 may extend in the second direction DR2 and may be arranged in the first direction DR1. The second pixel patterns PP2 may cross one of the data lines DL1 to DL12 on the plane (or in a plan view) as the second pixel patterns PP2 extend in the second direction DR2.

According to some embodiments, the first pixel patterns PP1 and the second pixel patterns PP2 may be located on different layers. For example, the first pixel patterns PP1 may be located on the same layer as the second connection electrode CNE20 (see FIG. 3), and the second pixel patterns PP2 may be located on the same layer as the first connection electrode CNE10 (see FIG. 3). Thus, the data lines DL1 to DL12 extending in the first direction DR1 and the first pixel patterns PP1 may be located on the same layer.

One end of the first pixel pattern PP1 may be connected to one end of the corresponding second pixel pattern PP2 through a first pixel contact hole PCT1, and the other end of the first pixel pattern PP1 may be directly connected to a corresponding pad of the first pads PD1. The other end of the second pixel pattern PP2 may be connected to the corresponding data lines DL7 to DL12 through a second pixel contact hole PCT2.

FIG. 7B illustrates a connection relationship between the first pixel connection lines PC-L and the data lines DL7 to DL12 included in the second left group DG2-L. The description of the connection relationship between the first pixel connection lines PC-L and the data lines DL7 to DL12 included in the second left group DG2-L may be equally applied to that of the connection relationship between the second pixel connection lines PC-R and the data lines DL7 to DL12 included in the second right group DG2-R, and thus, duplicated descriptions will be omitted. The first pixel connection lines PC-L may include first to sixth connection lines PC1 to PC6.

The seventh data line DL7 included in the second left group DG2-L may include a first-first pixel pattern PP1-1 extending in the first direction DR1 and a second-first pixel pattern PP2-1 extending in the second direction DR2.

One end of the First-first pixel pattern PP1-1 may be connected to one end of the second-first pixel pattern PP2-1 through the first contact hole PCT1. The first contact holes PCT1 to be described with reference to FIG. 7B may be defined to pass through the sixth insulating layer 60 described in FIG. 3. The other end of the first-first pixel pattern PP1-1 may be connected to the corresponding first pad PD1. The first-first pixel pattern PP1-1 may be located between the fifth data line DL5 and the sixth data line DL6.

One end of a second-first pixel pattern PP2-1 may be connected to one end of the first-first pixel pattern PP1-1 through the first contact hole PCT1, and the other end of the second-first pixel pattern PP2-1 may be connected to the seventh data line DL7. The second-first pixel pattern PP2-1 may cross the sixth data line DL6 on the plane (or in a plan view).

One end of a first-second pixel pattern PP1-2 may be connected to one end of a second-second pixel pattern PP2-2 through the first contact hole PCT1. The other end of the first-second pixel pattern PP1-2 may be connected to the corresponding first pad PD1. The first-second pixel patterns PP1-2 may be located between the fourth data line DL4 and the fifth data line DL5.

One end of a second-second pixel pattern PP2-2 may be connected to one end of the first-second pixel pattern PP1-2 through the first contact hole PCT1, and the other end of the second-second pixel pattern PP2-2 may be connected to the eighth data line DL8. The second-second pixel pattern PP2-2 may cross the fifth to sixth data lines DL5 to DL7 on the plane (or in a plan view).

One end of a first-third pixel pattern PP1-3 may be connected to one end of a second-third pixel pattern PP2-3 through the first contact hole PCT1. The other end of the first-third pixel pattern PP1-3 may be connected to the corresponding first pad PD1. The first-third pixel patterns PP1-3 may be located between the third data line DL3 and the fourth data line DL4.

One end of the second-third pixel pattern PP2-3 may be connected to one end of the first-third pixel pattern PP1-3 through the first contact hole PCT1, and the other end of the second-third pixel pattern PP2-3 may be connected to the ninth data line DL9. The second-third pixel patterns PP2-3 may cross the fourth to eighth data lines DL4 to DL5 on the plane (or in a plan view).

One end of a first-fourth pixel pattern PP1-4 may be connected to one end of a second-fourth pixel pattern PP2-4 through the first contact hole PCT1. The other end of the first-fourth pixel pattern PP1-4 may be connected to the corresponding first pad PD1. The first-fourth pixel patterns PP1-4 may be located between the second data line DL2 and the third data line DL3.

One end of a second-fourth pixel pattern PP2-4 may be connected to one end of the first-fourth pixel pattern PP1-4 through the first contact hole PCT1, and the other end of the second-fourth pixel pattern PP2-4 may be connected to the tenth data line DL10. The second-fourth pixel patterns PP2-4 may cross the third to ninth data lines DL3 to DL9 on the plane (or in a plan view).

One end of a first-fifth pixel pattern PP1-5 may be connected to one end of a second-fifth pixel pattern PP2-5 through the first contact hole PCT1. The other end of the first-fifth pixel pattern PP1-5 may be connected to the corresponding first pad PD1. The first-fifth pixel patterns PP1-5 may be located between the second data line DL2 and the third data line DL1.

One end of a second-fifth pixel pattern PP2-5 may be connected to one end of the first-fifth pixel pattern PP1-5 through the first contact hole PCT1, and the other end of the second-fifth pixel pattern PP2-5 may be connected to the eleventh data line DL11. The second-fifth pixel patterns PP2-5 may cross the second to tenth data lines DL2 to DL10 on the plane (or in a plan view).

One end of a first-sixth pixel pattern PP1-6 may be connected to one end of a second-sixth pixel pattern PP2-6 through the first contact hole PCT1. The other end of the first-sixth pixel pattern PP1-6 may be connected to the corresponding first pad PD1. The first-sixth pixel patterns PP1-6 may be located between the first data line DL1 and the data line overlapping the central axis CX (see FIG. 7A).

One end of a second-sixth pixel pattern PP2-6 may be connected to one end of the first-sixth pixel pattern PP1-6 through the first contact hole PCT1, and the other end of the second-sixth pixel pattern PP2-6 may be connected to the twelfth data line DL12. The second-sixth pixel patterns PP2-6 may cross the first to eleventh data lines DL1 to DL11 on the plane (or in a plan view).

Referring again to FIG. 7A, an area of the data connection line DCL, on which the second pixel patterns PP2 included in the first pixel connection lines PC-L are located, may be defined as a first pixel pattern area DA-L, and an area of the data connection line DCL, on which the second pixel connection lines PC-R are located, may be defined as a second pixel pattern area DA-R.

According to some embodiments, each of the first pixel pattern area DA-L and the second pixel pattern area DA-R may have an inverted triangular shape on the plane (or in a plan view). In addition, the first pixel pattern area DA-L and the second pixel pattern area DA-R may have symmetrical shapes with respect to the central axis CX.

According to some embodiments, a mesh structure MST may be located between the first pixel pattern area DA-L and the second pixel pattern area DA-R. As will be described later with reference to FIG. 8, the mesh structure MST may be arranged over the entire area of the active area AA except for a partial area. In FIG. 7A, for convenience of description, the mesh structure MST located between the first pixel pattern area DA-L and the second pixel pattern area DA-R is indicated by a thick line. An area on which the mesh structure MST is located between the first pixel pattern area DA-L and the second pixel pattern area DA-R may be defined as a pixel dummy area DM-D.

The mesh structure MST may include first mesh lines M1 extending in the first direction DR1 and second mesh lines M2 extending in the second direction DR2. The first mesh lines M1 and the second mesh lines M2 may cross each other to define mesh openings overlapping the emission area PXA and the sensing area SA, which are described in FIG. 3. The first mesh lines M1 and the second mesh lines M2 may have a net shape on the plane (or in a plan view).

According to some embodiments, the first mesh lines M1 and the second mesh lines M2 may be located on different layers. For example, the first mesh lines M1 may be located on the same layer as the second connection electrode CNE20 described in FIG. 3, and the second mesh lines M2 may be located on the same layer as the first connection electrode CNE10 described in FIG. 3.

The first mesh lines M1 may extend in the first direction DR1 together with the first pixel patterns PP1 and the data lines DL1 to DL12, which are located on the same layer, and may be spaced apart from each other in the second direction DR2.

The second mesh lines M2 may extend in the second direction DR2 together with the second pixel pattern PP2, which are located on the same layer, and may be spaced apart from each other in the second direction DR2. The second pixel pattern PP2 and the second mesh line M2, which are located in the same row, may be aligned in the second direction DR2 and may be patterned to be disconnected from each other in the second direction DR2.

According to the present disclosure, the data lines DL7 to DL12 located farther from the central axis CX among the data lines DL1 to DL12 may be connected to the first pads PD1 via the active area AA through the data connection line DCL to reduce a dead space DS for directly connecting the data lines DL7 to DL12 to the first pads PD1. Thus, the display panel 100 having a reduced peripheral area NAA may be provided.

In FIG. 8, the first pixel pattern area DA-L, the second pixel pattern area DA-R, and the pixel dummy area DM-D, which are described in FIG. 7A, are illustrated by dotted lines, and the constituents described with reference to FIG. 7A will be omitted.

Referring to FIG. 8, the display panel 100 includes lead-out lines RL1 to RL12 connected to corresponding sensors FX (see FIG. 3) and a sensor connection line SCL connected to corresponding lead-out lines RL1 to RL12. The sensor connection line SCL may include first lead-out connection lines SC-L located at one side of the active area AA and connected to the corresponding lead-out lines RL1 to RL12 and second lead-out connection lines SC-R located at the other side of the active area AA and connected to the corresponding lead-out lines RL1 to RL12.

Each of the lead-out lines RL1 to RL12 located at the one side (left side) and the other side (right side) of the active area AA with respect to the central axis CX may be located on the same layer as one of the first connection electrode CNE10 and the second connection electrode CNE20, which are described with reference to FIG. 3. Thus, the data lines DL1 to DL12, the first pixel patterns PP1, and the first mesh lines M1 of the constituents described with reference to FIG. 7A may be located on the same layer as at least a portion of the lead-out lines RL1 to RL12. Each of the lead-out lines RL1 to RL12 may extend in the first direction DR1 and may be arranged in the second direction DR2.

The lead-out lines RL1 to RL12 located at one side of the active area AA may be divided into a first left group RG1-L and a second left group RG2-L. The lead-out lines RL7-RL12 included in the second left group RG2-L may be directly connected to a second pad area PA-FX located at the left side among second pads PA-FX defined on the peripheral area NAA. In more detail, the lead-out lines RL7 to RL12 may be directly connected to a corresponding pad of the second pads PD2 provided on the second pad area PA-FX located at the left side. The second pad areas PA-FX may be spaced apart from each other in the second direction DR2 with the first pad area PA-PX therebetween.

The lead-out lines RL1 to RL6 included in the first left group RG1-L may be connected to a corresponding pad of the second pads PD2 through the first read-out connection lines SC-L in the sensor connection line SCL.

The lead-out lines RL1 to RL12 located at the other side of the active area AA may be divided into a first right group RG1-R and a second right group RG2-R. The lead-out lines RL7 to RL12 included in the second right group RG2-R may be directly connected to the second pad area PA-FX located at the right side of the second pad areas PA-FX. In more detail, the lead-out lines RL7 to RL12 may be directly connected to a corresponding pad of the second pads PD2 provided on the second pad area PA-FX located at the right side.

The lead-out lines RL1 to RL6 included in the first right group RG1-R may be connected to a corresponding pad of the second pads PD2 through the second read-out connection lines SC-R in the sensor connection lines SCL.

According to some embodiments, each of the first lead-out connection lines SC-L and the second lead-out connection lines SC-R includes a plurality of first sensor patterns SP1 and second sensor patterns SP2 connected to the corresponding first sensor pattern SP1. Each of the first sensor patterns SP1 may extend in the first direction DR1 and be located between the corresponding lead-out lines of the lead-out lines RL1 to RL12 included in the first left group RG1-L and the first right group RG1-R.

Each of the second sensor patterns SP2 may extend in the second direction DR2 and be arranged in the first direction DR1. The second sensor patterns SP2 extend in the second direction DR2 to cross one of the data lines DL1 to DL12 described in FIG. 7A and the lead-out lines RL7 to RL12 included in the second left group RG2-L and the second right group RG2-R on the plane (or in a plan view).

According to some embodiments, the first sensor patterns SP1 and the second sensor patterns SP2 may be located on different layers. For example, the first sensor patterns SP1 may be located on the same layer as the second connection electrode CNE20 (see FIG. 3), and the second sensor patterns SP2 may be located on the same layer as the first connection electrode CNE10 (see FIG. 3). Thus, the data lines DL1 to DL12, the lead-out lines RL1 to RL12, and the first mesh lines M1, which extend in the first direction DR1, may be the same layer as the first sensor patterns SP1.

One end of the first sensor pattern PP1 may be connected to one end of the corresponding second sensor pattern SP2 through the first sensor contact hole SCT1, and the other end of the first sensor pattern SP1 may be directly connected to a corresponding pad of the second pads PD2. The other end of the second sensor pattern PP2 may be connected to corresponding lead-out lines RL7 to RL12 through the second sensor contact hole SCT2.

According to some embodiments, the lead-out lines RL1 to RL6 connected to the sensors FX (see FIG. 3) adjacent to the center axis CX may be connected to the second pads PD2 through the sensor connection line SCL, and thus, the sensors FX may be located between the pixels PX as illustrated in FIG. 3. Thus, the display panel 100 having improved sensing sensitivity may be provided.

According to some embodiments, the second sensor patterns SP2 may have the same width in the second direction DR2.

An area of the sensor connection line SCL, on which the second sensor patterns SP2 included in the first lead-out connection lines SC-L are located, may be defined as a first sensor pattern area RA-L, and an area of the sensor connection line SCL, on which the second sensor patterns SP2 included in the two sensor connection lines SC-R are located, may be defined as a second sensor pattern area RA-R.

According to some embodiments, each of the first sensor pattern area RA-L and the second sensor pattern area RA-R may have a trapezoidal shape on the plane (or in a plan view). In more detail, each of the first sensor pattern area RA-L and the second sensor pattern area RA-R may have a parallelogram shape. In addition, the first sensor pattern area RA-L and the second sensor pattern area RA-R may have symmetrical shapes with respect to the center axis CX.

The first sensor pattern area RA-L may be located farther from the first pad area PA-PX than the first pixel pattern area DA-L, and the second sensor pattern area RA-R may be located farther from the first pad area PA-PX than the second pixel area DA-R.

A mesh structure MST may be located between the first sensor pattern area RA-L and the second sensor pattern area RA-R. As will be described later with reference to FIG. 8, the mesh structure MST may be located over the entire area of the active area AA except for a partial area. In FIG. 7A, for convenience of description, the mesh structure MST located between the first sensor pattern area RA-L and the second sensor pattern area RA-R is indicated by a thick line. An area on which the mesh structure MST is located between the first sensor pattern area RA-L and the second sensor pattern area RA-R may be defined as a sensor dummy area DM-R.

The mesh structure MST may include first mesh lines M1 extending in the first direction DR1 and second mesh lines M2 extending in the second direction DR2. The first mesh lines M1 and the second mesh lines M2 may cross each other to define mesh openings overlapping the emission area PXA and the sensing area SA, which are described in FIG. 3. The first mesh lines M1 and the second mesh lines M2 may have a net shape on the plane (or in a plan view).

According to some embodiments, the first mesh lines M1 and the second mesh lines M2 may be located on different layers. For example, the first mesh lines M1 may be located on the same layer as the second connection electrode CNE20 described in FIG. 3, and the second mesh lines M2 may be located on the same layer as the first connection electrode CNE10 described in FIG. 3.

The first mesh lines M1 extend in the first direction DR1 together with the first sensor patterns SP1 and the lead-out lines RL1 to RL12, which are located on the same layer, and may be spaced apart from each other in the second direction DR2.

The second mesh lines M2 may extend in the second direction DR2 together with the second sensor pattern SP2, which are located on the same layer, and may be spaced apart from each other in the second direction DR2. The second sensor pattern SP2 and the second mesh line M2, which are located on the same row, may be aligned in the second direction DR2 and may be patterned to be disconnected from each other in the second direction DR2.

According to some embodiments, widths of the second mesh lines M2 located on the sensor dummy area DM-R in the second direction DR2 may be the same as each other. For example, the second mesh line M2 aligned with the second sensor pattern SP2 connected to the first lead-out line RL1 in the second direction DR2 may have the same width as the second mesh line M2 aligned with the second sensor pattern SP2 connected to the sixth lead-out line RL6 in the second direction DR2.

Referring to FIG. 9, the display panel 100 may include a signal line SL and a mesh structure MST. The signal line SL may be adjacent to a boundary between the active area AA and the peripheral area NAA and may surround the active area AA. One side of the signal line SL may be connected to the third pad PD3 provided on the third pad area PA-PW located at the left side, and one side of the signal line SL may be connected to the third pad PD3 of the third pad area PA-PW located at the right side. The signal line SL may be provided with one of the first driving voltage ELVDD, the second driving voltage ELVSS, the first initialization voltage VINT1, the second initialization voltage VINT2, and the reset voltage Vrst, which are described with reference to FIG. 3, but the embodiments of the present disclosure are not limited thereto.

The signal line SL according to some embodiments may be connected to the mesh structure MST. Thus, one of the first driving voltage ELVDD, the second driving voltage ELVSS, the first initialization voltage VINT1, the second initialization voltage VINT2, and the reset voltage Vrst may be applied to the mesh structure MST.

As described above, the mesh structure MST may include first mesh lines M1 extending in the first direction DR1 and second mesh lines M2 extending in the second direction DR2. The first mesh lines M1 and the second mesh lines M2 may cross each other to define mesh openings overlapping the emission area PXA and the sensing area SA, which are described in FIG. 3. The first mesh lines M1 and the second mesh lines M2 may have a net shape on the plane (or in a plan view).

According to some embodiments, the first mesh lines M1 and the second mesh lines M2 may be located on different layers. For example, the first mesh lines M1 may be located on the same layer as the second connection electrode CNE20 described in FIG. 3, and the second mesh lines M2 may be located on the same layer as the first connection electrode CNE10 described in FIG. 3. Some of the first mesh lines M1 may be connected to each other through a mesh contact hole MCT defined in the sixth insulating layer 60 (see FIG. 6) at a point at which the second mesh lines M2 is intersected. Thus, the display panel 100 may uniformly provide the same signal as a signal, which is provided through the signal line SL through the first mash lines M1 and the second mesh lines M2, over the entire area except for a partial area of the active area AA.

The first mesh lines M1 and the second mesh lines M2, which are included in the mesh structure MST, may be located on the entire area of the active area AA except for one area of the active area AA.

The one area on which the mesh structure MST is not located may be a first pixel pattern area DA-L, a second pixel pattern area DA-R, a first sensor pattern area RA-L, and a second sensor pattern area RA-R. Patterns extending in the second direction DR2 among patterns provided on the first pixel pattern area DA-L, the second pixel pattern area DA-R, the first sensor pattern area RA-L, and the second sensor pattern area RA-R may be located on the same layer as the second mesh lines M2 and be patterned through the same process. Thus, the patterns extending in the second direction DR2 may be formed by disconnecting portions of the second mesh lines M2.

In addition, patterns extending in the first direction DR1 among patterns provided on the first pixel pattern area DA-L, the second pixel pattern area DA-R, the first sensor pattern area RA-L, and the second sensor pattern area RA-R may be located on the same layer as the first mesh lines M1 and be patterned through the same process.

As described above, an area on which the mesh structure MST is located between the first sensor pattern area RA-L and the second sensor pattern area RA-R may be defined as a sensor dummy area DM-R. Widths of the second mesh lines M2 located on the sensor dummy area DM-R in the second direction DR2 may be the same as each other. For example, the second mesh line M2 aligned with the second sensor pattern SP2 connected to the first lead-out line RL1 (see FIG. 8) in the second direction DR2 may have a first width WD1, and the second mesh line M2 aligned with the second sensor pattern SP2 connected to the sixth lead-out line RL6 (see FIG. 8) in the second direction DR2 may have a second width WD2. Here, the first width WD1 and the second width WD2 may be the same. The sensor dummy area DM-R may have a parallelogram shape on the plane (or in a plan view).

According to some embodiments, a width of each of the second mesh lines M2 included in the sensor dummy area DM-R in the second direction DR2 may be more than 5% of a width of the active area AA in the second direction DR2.

When a signal provided to the signal line SL is, for example, the second driving voltage ELVSS, the mesh structure MST may be located on the active area AA to reduce resistance of the second driving voltage ELVSS. Here, when the sensor connection line SCL is used to form the sensors FX on the active area AA, as an area between the first sensor pattern area RA-L and the second sensor pattern area RA-R is narrowed, for example, when each of the first sensor pattern area RA-L and the second sensor pattern area RA-R has a triangular shape or an inverted triangular shape, widths of the second mesh lines M2 provided on the sensor dummy area DM-R may be different from each other, and the second mesh line located between adjacent vertexes may have a width less than that of each of other second mesh lines located on the sensor dummy area DM-R. As a result, a limitation such as an increase in resistance of the second driving voltage ELVSS due to a bottleneck phenomenon may occur on the sensor dummy area DM-R of which a width is narrowed.

According to some embodiments, the width of the sensor dummy area DM-R located between the first sensor pattern area RA-L and the second sensor pattern area RA-R in the second direction DR2 may be constant, and thus, the resistance of the second driving voltage ELVSS may be stably reduced. Thus, the display device 1000 including the display panel 100 having the improved quality may be provided.

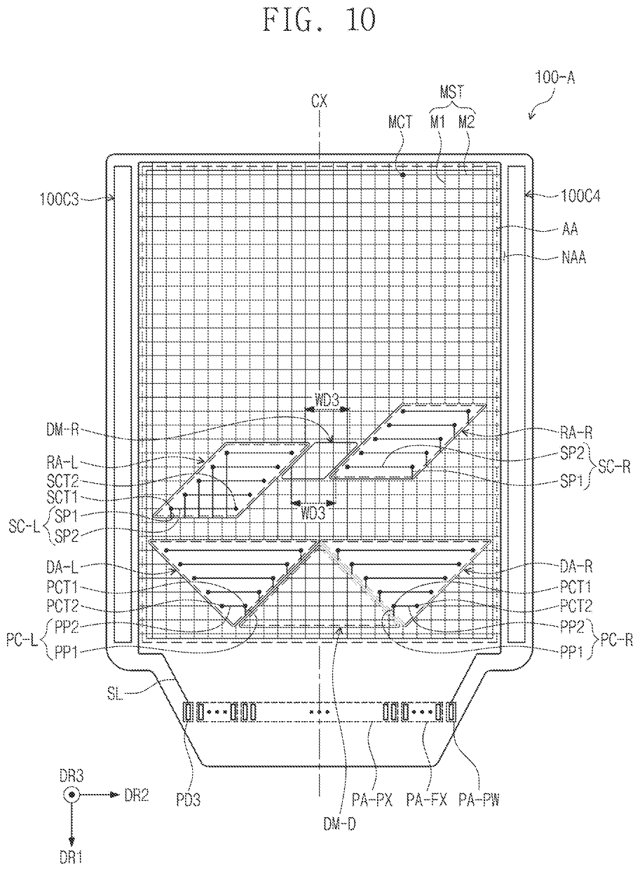

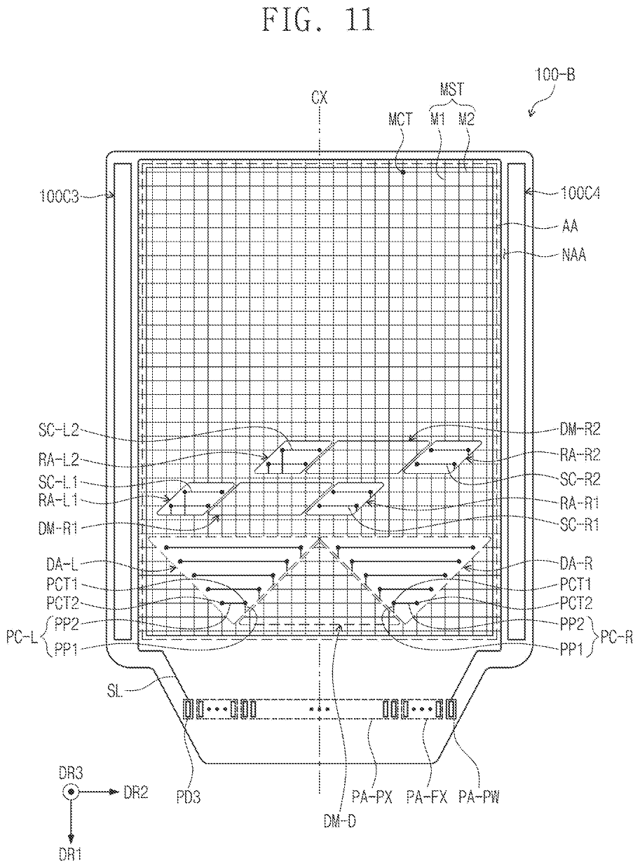

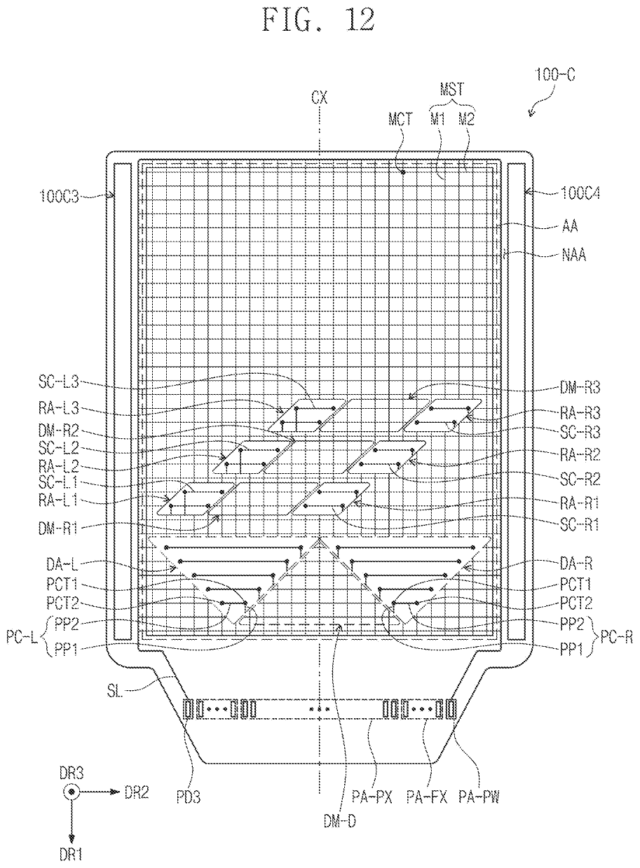

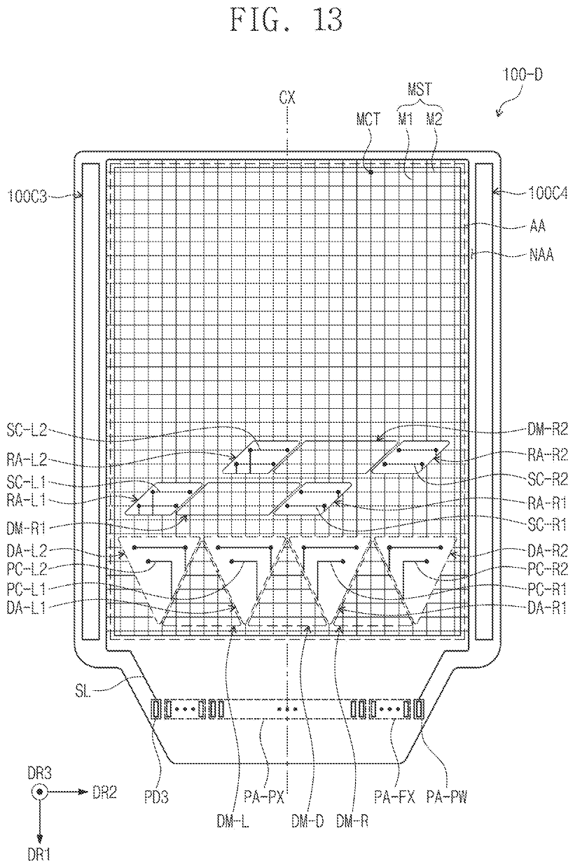

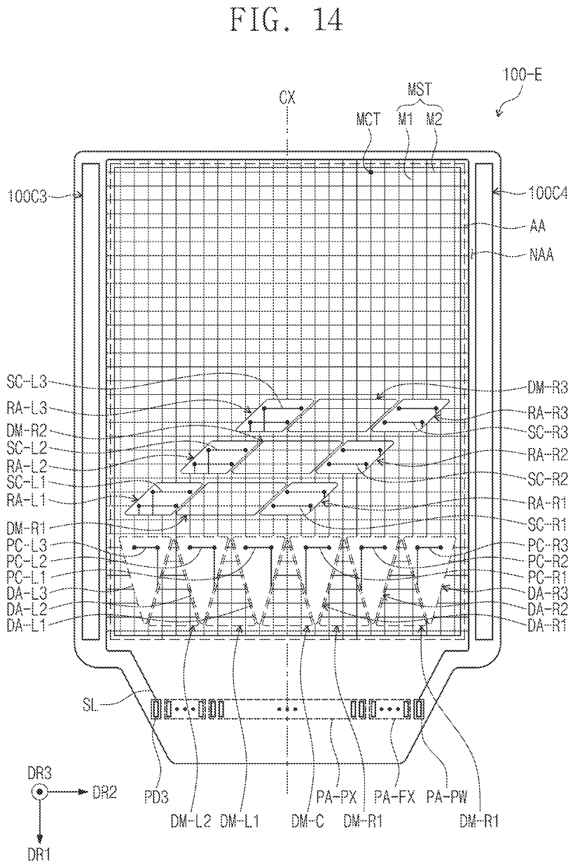

FIG. 10 is a plan view of a display panel according to some embodiments of the present disclosure. FIG. 11 is a plan view of a display panel according to some embodiments of the present disclosure. FIG. 12 is a plan view of a display panel according to some embodiments of the present disclosure. FIG. 13 is a plan view of a display panel according to some embodiments of the present disclosure. FIG. 14 is a plan view of a display panel according to some embodiments of the present disclosure.

The same/similar reference numerals are used for the same/similar configurations as the configurations described in FIGS. 1 to 9, and redundant descriptions are omitted. FIGS. 10 to 14 illustrate the mesh structure MST located on the entire area of the active area AA except for a partial area as illustrated in FIG. 8, and the pixel connection lines respectively provided on the pixel pattern areas and the sensor connection lines respectively provided on the sensor pattern areas will be briefly indicated as areas. In addition, the data lines DL1 to DL12 and the lead-out lines RL1 to RL12 described in FIG. 7A will be omitted.

Referring to FIG. 10, a display panel 100-A according to some embodiments may include first pixel connection lines PC-L connected to some of the data lines located at the left side of the active area AA and second pixel connection lines PC-R connected to some of the data lines located at the right side of the active area AA with respect to the central axis CX.

Each of the first pixel connection lines PC-L and the second pixel connection lines PC-R may include a first pixel pattern PP1 and a second pixel pattern PP2 connected to the first pixel pattern PP1. Each of the first pixel patterns PP1 may extend in the first direction DR1 and may be located between corresponding data lines of the data lines. An area on which the second pixel patterns PP2 are located at the left side with respect to the central axis CX may be defined as a first pixel pattern area DA-L, and an area on which the second pixel patterns PP2 are located at the right side with respect to the central axis CX may be defined as a second pixel pattern area DA-R.

According to some embodiments, each of the first pixel pattern area DA-L and the second pixel pattern area DA-R may have an inverted triangular shape on the plane (or in a plan view). In addition, the first pixel pattern area DA-L and the second pixel pattern area DA-R may have symmetrical shapes with respect to the central axis CX. An area on which the mesh structure MST is located between the first pixel pattern area DA-L and the second pixel pattern area DA-R may be defined as a pixel dummy area DM-D.

The display panel 100-A may include a first sensor pattern area RA-L connected to some of the lead-out lines located at the left side of the active area AA with respect to the central axis CX and a second sensor pattern area RA-R connected to some of the lead-out lines located at the right side of the active area AA with respect to the central axis CX.

The first lead-out connection lines SC-L and the second sensor connection lines SC-R may include a first sensor pattern SP1 and a second sensor pattern SP2 connected to a corresponding first sensor pattern SP1. Each of the first sensor patterns SP1 may extend in the first direction DR1 and may be located between corresponding lead-out lines of the lead-out lines. An area on which the second sensor patterns SP2 are located at the left side with respect to the central axis CX may be defined as a first sensor pattern area RA-L, and an area on which the second sensor patterns SP2 are located at the right side with respect to the central axis CX may be defined as a second sensor pattern area RA-R.

Each of the first sensor pattern area RA-L and the second sensor pattern area RA-R may have a trapezoidal shape on the plane (or in a plan view). In more detail, each of the first sensor pattern area RA-L and the second sensor pattern area RA-R may have a parallelogram shape.

According to some embodiments, the parallelogram shape of the second sensor pattern area RA-R may be shifted in an oblique direction with respect to each of the first direction DR1 and the second direction DR2 when compared to the parallelogram shape of the first sensor pattern area RA-L. In this case, an area on which the mesh structure MST is located between the first sensor pattern area RA-L and the second sensor pattern area RA-R may be defined as a sensor dummy area DM-R. The sensor dummy area DM-R may have a parallelogram shape.

According to some embodiments, the second mesh lines M2 provided on the sensor dummy area DM-R may have the same width. For example, the second mesh line M2 located between the second sensor pattern SP2 located at the uppermost end of the first sensor pattern area RA-L and the second sensor pattern SP2 located at a second position from the lowermost end of the second sensor pattern RA-R may have a third width WD3.

The second mesh line M2 located between the second sensor pattern SP2 located at a second position from the uppermost end of the first sensor pattern area RA-L and the second sensor pattern SP2 located at the lowermost end of the second sensor pattern RA-R may have a third width WD3. According to some embodiments, the third width WD3 and the fourth width WD4 may be equal to each other.

Referring to FIG. 11, a display panel 100-B according to some embodiments may include first pixel connection lines PC-L connected to some of the data lines located at the left side of the active area AA and second pixel connection lines PC-R connected to some of the data lines located at the right side of the active area AA with respect to the central axis CX.

Each of the first pixel connection lines PC-L and the second pixel connection lines PC-R may include a first pixel pattern PP1 and a second pixel pattern PP2 connected to the first pixel pattern PP1. Each of the first pixel patterns PP1 may extend in the first direction DR1 and may be located between corresponding data lines of the data lines. An area on which the second pixel patterns PP2 are located at the left side with respect to the central axis CX may be defined as a first pixel pattern area DA-L, and an area on which the second pixel patterns PP2 are located at the right side with respect to the central axis CX may be defined as a second pixel pattern area DA-R.

According to some embodiments, each of the first pixel pattern area DA-L and the second pixel pattern area DA-R may have an inverted triangular shape on the plane (or in a plan view). In addition, the first pixel pattern area DA-L and the second pixel pattern area DA-R may have symmetrical shapes with respect to the central axis CX. An area on which the mesh structure MST is located between the first pixel pattern area DA-L and the second pixel pattern area DA-R may be defined as a pixel dummy area DM-D.

The display panel 100-B may include a first-first sensor connection lines SC-L1 connected to some of the lead-out lines located at the left side of the active area AA with respect to the central axis CX and a first-second sensor connection lines SC-L2 connected to other lead-out lines.

Each of the first-first sensor connection lines SC-L1 and first-second sensor connection lines SC-L2 may include a first sensor pattern extending in the first direction DR1 and a second sensor pattern connected to the first sensor pattern and extending in the second direction DR2. An area on which the second sensor patterns included in the first-first sensor connection lines SC-L1 are located may be defined as the first-first sensor pattern area RA-L1, and an area on which the second sensor patterns included in the first-second sensor connection lines SC-L2 are located may be defined as a first-second sensor pattern area RA-L2.

According to some embodiments, each of the first-first sensor pattern area RA-L1 and the first-second sensor pattern area RA-L2 may have a parallelogram shape. The first-second sensor pattern area RA-L2 may be further away from the first pad area PA-PX than the first-first sensor pattern area RA-L1 and may be shifted in an oblique direction with respect to each of the first and second directions DR1 and DR2.

The display panel 100-B may include a second-first sensor connection lines SC-R1 connected to some of the lead-out lines located at the right side of the active area AA with respect to the central axis CX and a second-second sensor connection lines SC-R2 connected to other lead-out lines.

Each of the second-first sensor connection lines SC-R1 and second-second sensor connection lines SC-R2 may include a first sensor pattern extending in the first direction DR1 and a second sensor pattern connected to the first sensor pattern and extending in the second direction DR2. An area on which the second sensor patterns included in the second-first sensor connection lines SC-R1 are located may be defined as the second-first sensor pattern area RA-R1, and an area on which the second sensor patterns included in the second-second sensor connection lines SC-R2 are located may be defined as a second-second sensor pattern area RA-R2.

According to some embodiments, each of the second-first sensor pattern area RA-R1 and the second-second sensor pattern area RA-R2 may have a parallelogram shape. The second-second sensor pattern area RA-R2 may be further away from the first pad area PA-PX than the second-first sensor pattern area RA-R1 and may be shifted in an oblique direction with respect to each of the first and second directions DR1 and DR2.

However, the embodiments of the present disclosure are not limited thereto, and at least one of the first-first sensor pattern area RA-L1, the first-second sensor pattern area RA-L2, the second-first sensor pattern area RA-R1, or the second-second sensor pattern area RA-R2 may have a triangular shape or an inverted triangular shape.

According to some embodiments, a mesh structure MST may be located between the first-first sensor pattern area RA-L1 and the second-first sensor pattern area RA-R1. An area on which the mesh structure MST is located between the first-first sensor pattern area RA-L1 and the second-first sensor pattern area RA-R1 may be defined as a first sensor dummy area DM-R1. Widths of the second mesh lines M2 located on the first sensor dummy area DM-R1 in the second direction DR2 may be the same as each other.

A mesh structure MST may be located between the first-second sensor pattern area RA-L2 and the second-second sensor pattern area RA-R2. An area on which the mesh structure MST is located between the first-second sensor pattern area RA-L2 and the second-second sensor pattern area RA-R2 may be defined as a second sensor dummy area DM-R2. Widths of the second mesh lines M2 located on the second sensor dummy area DM-R2 in the second direction DR2 may be the same as each other.

Referring to FIG. 12, a display panel 100-C according to some embodiments may include first pixel connection lines PC-L connected to some of the data lines located at the left side of the active area AA and second pixel connection lines PC-R connected to some of the data lines located at the right side of the active area AA with respect to the central axis CX.

Each of the first pixel connection lines PC-L and the second pixel connection lines PC-R may include a first pixel pattern PP1 and a second pixel pattern PP2 connected to the first pixel pattern PP1. Each of the first pixel patterns PP1 may extend in the first direction DR1 and may be located between corresponding data lines of the data lines. An area on which the second pixel patterns PP2 are located at the left side with respect to the central axis CX may be defined as a first pixel pattern area DA-L, and an area on which the second pixel patterns PP2 are located at the right side with respect to the central axis CX may be defined as a second pixel pattern area DA-R.

According to some embodiments, each of the first pixel pattern area DA-L and the second pixel pattern area DA-R may have an inverted triangular shape on the plane (or in a plan view). In addition, the first pixel pattern area DA-L and the second pixel pattern area DA-R may have symmetrical shapes with respect to the central axis CX. An area on which the mesh structure MST is located between the first pixel pattern area DA-L and the second pixel pattern area DA-R may be defined as a pixel dummy area DM-D.

The display panel 100-C may include first-first sensor connection lines SC-L1 connected to some of the lead-out lines located at the left side of the active area AA with respect to the central axis CX, first-second sensor connection lines SC-L2 connected to other lead-out lines, and first-third sensor connection lines SC-L3 connected to other lead-out lines.

Each of the first-first sensor connection lines SC-L1, the first-second sensor connection lines SC-L2, and first-third sensor connection lines SC-L3 may include a first sensor pattern extending in the first direction DR1 and a second sensor pattern connected to the first sensor pattern and extending in the second direction DR2. An area on which the second sensor patterns included in the first-first sensor connection lines SC-L1 are located may be defined as the first-first sensor pattern area RA-L1, an area on which the second sensor patterns included in the first-second sensor connection lines SC-L2 are located may be defined as a first-second sensor pattern area RA-L2, and an area on which the second sensor patterns included in the first-third sensor connection lines SC-L3 are located may be defined as a first-third sensor pattern area RA-L3.

According to some embodiments, each of the first-first sensor pattern area RA-L1, the first-second sensor pattern area RA-L2, and the first-third sensor pattern area RA-L3 may have a parallelogram shape. The first-second sensor pattern area RA-L2 may be further away from the first pad area PA-PX than the first-first sensor pattern area RA-L1 and may be shifted in an oblique direction with respect to each of the first and second directions DR1 and DR2.

The first-third sensor pattern area RA-L3 may be further away from the first pad area PA-PX than the first-second sensor pattern area RA-L2 and be shifted in an oblique direction.

The display panel 100-C may include second-first sensor connection lines SC-R1 connected to some of the lead-out lines located at the right side of the active area AA with respect to the central axis CX, second-second sensor connection lines SC-R2 connected to other lead-out lines, and second-third sensor connection lines SC-R3 connected to other lead-out lines.

Each of the second-first sensor connection lines SC-R1, the second-second sensor connection lines SC-R2, and second-third sensor connection lines SC-R3 may include a first sensor pattern extending in the first direction DR1 and a second sensor pattern connected to the first sensor pattern and extending in the second direction DR2. An area on which the second sensor patterns included in the second-first sensor connection lines SC-R1 are located may be defined as the second-first sensor pattern area RA-R1, an area on which the second sensor patterns included in the second-second sensor connection lines SC-R2 are located may be defined as a second-second sensor pattern area RA-R2, and an area on which the second sensor patterns included in the second-third sensor connection lines SC-R3 are located may be defined as a second-third sensor pattern area RA-R3.

According to some embodiments, each of the second-first sensor pattern area RA-R1, the second-second sensor pattern area RA-R2, and the second-third sensor pattern area RA-R3 may have a parallelogram shape. The second-second sensor pattern area RA-R2 may be further away from the first pad area PA-PX than the second-first sensor pattern area RA-R1 and may be shifted in an oblique direction with respect to each of the first and second directions DR1 and DR2.

The second-third sensor pattern area RA-R3 may be further away from the first pad area PA-PX than the second-second sensor pattern area RA-R2 and be shifted in an oblique direction.

However, the embodiments of the present disclosure are not limited thereto, and at least one of the first-first sensor pattern area RA-L1, the first-second sensor pattern area RA-L2, the first-third sensor pattern area RA-L3, the second-first sensor pattern area RA-R1, the second-second sensor pattern area RA-R2, or the second-third sensor pattern area RA-R3 may have a triangular shape or an inverted triangular shape.

According to some embodiments, a mesh structure MST may be located between the first-first sensor pattern area RA-L1 and the second-first sensor pattern area RA-R1. An area on which the mesh structure MST is located between the first-first sensor pattern area RA-L1 and the second-first sensor pattern area RA-R1 may be defined as a first sensor dummy area DM-R1. Widths of the second mesh lines M2 located on the first sensor dummy area DM-R1 in the second direction DR2 may be the same as each other.

A mesh structure MST may be located between the first-second sensor pattern area RA-L2 and the second-second sensor pattern area RA-R2. An area on which the mesh structure MST is located between the first-second sensor pattern area RA-L2 and the second-second sensor pattern area RA-R2 may be defined as a second sensor dummy area DM-R2. Widths of the second mesh lines M2 located on the second sensor dummy area DM-R2 in the second direction DR2 may be the same as each other.

A mesh structure MST may be located between the first-third sensor pattern area RA-L3 and the second-third sensor pattern area RA-R3. An area on which the mesh structure MST is located between the first-third sensor pattern area RA-L3 and the second-third sensor pattern area RA-R3 may be defined as a third sensor dummy area DM-R3. Widths of the second mesh lines M2 located on the third sensor dummy area DM-R3 in the second direction DR2 may be the same as each other.

Referring to FIG. 13, a display panel 100-D according to some embodiments may include first-first pixel connection lines PC-L1 connected to some of the data lines located at the left side of the active area AA and first-second pixel connection lines PC-L2 connected to some of other data lines with respect to the central axis CX.

Each of the first-first pixel connection lines PC-L1 and the first-second pixel connection lines PC-L2 may include a first pixel pattern and a second pixel pattern connected to the first pixel pattern. Each of the first pixel patterns may extend in the first direction DR1 and may be located between corresponding data lines of the data lines. Each of the second pixel patterns may extend in the second direction DR2.

An area on which the second pixel patterns of the first-first pixel connection lines PC-L1 are located may be defined as the first-first pixel pattern area DA-L1, and an area on which the second pixel patterns of the first-second pixel connection lines PC-L2 are located may be defined as a first-second pixel pattern area DA-L2.

The display panel 100-D may include a second-first pixel connection lines PC-R1 connected to some of the data lines located at the right side of the active area AA with respect to the central axis CX and a second-second pixel connection lines PC-R2 connected to other data lines.

Each of the second-first pixel connection lines PC-R1 and the second-second pixel connection lines PC-R2 may include a first pixel pattern and a second pixel pattern connected to the first pixel pattern. Each of the first pixel patterns may extend in the first direction DR1 and may be located between corresponding data lines of the data lines. Each of the second pixel patterns may extend in the second direction DR2.

An area on which the second pixel patterns of the second-first pixel connection lines PC-R1 are located may be defined as the second-first pixel pattern area DA-R1, and an area on which the second pixel patterns of the second-second pixel connection lines PC-R2 are located may be defined as a second-second pixel pattern area DA-R2.

According to some embodiments, each of the first-first pixel pattern area DA-L1, the first-second pixel pattern area DA-L2, the second-first pixel pattern area DA-R1, and the second-second pixel pattern area DA-R2 may have an inverted triangular shape on the plane (or in a plan view).

In addition, the first-first pixel pattern area DA-L1 and the second-first pixel pattern area DA-R1 may have symmetrical shapes with respect to the center layer CX, and the first-second pixel pattern area DA-L2 and the second-second pixel pattern area DA-R2 may have symmetrical shapes with respect to the center layer CX.

An area on which the mesh structure MST is located between the first-first pixel pattern area DA-L1 and the second-first pixel pattern area DA-R1 may be defined as a central pixel dummy area DM-D, an area on which the mesh structure MST is located between the first-second pixel pattern area DA-L2 and the first-first pixel pattern area DA-L1 may be defined as a left pixel dummy area DM-L, and an area on which the mesh structure MST is located between the second-second pixel pattern area DA-R2 and the second-first pixel pattern area DA-R1 may be defined as a right pixel dummy area DM-R. Each of the dummy areas DM-D, DM-L, and DM-R may have a triangular shape on the plane (or in a plan view).

The display panel 100-D may include a first-first sensor connection lines SC-L1 connected to some of the lead-out lines located at the left side of the active area AA with respect to the central axis CX and a first-second sensor connection lines SC-L2 connected to other lead-out lines.

Each of the first-first sensor connection lines SC-L1 and first-second sensor connection lines SC-L2 may include a first sensor pattern extending in the first direction DR1 and a second sensor pattern connected to the first sensor pattern and extending in the second direction DR2. An area on which the second sensor patterns included in the first-first sensor connection lines SC-L1 are located may be defined as the first-first sensor pattern area RA-L1, and an area on which the second sensor patterns included in the first-second sensor connection lines SC-L2 are located may be defined as a first-second sensor pattern area RA-L2.

According to some embodiments, each of the first-first sensor pattern area RA-L1 and the first-second sensor pattern area RA-L2 may have a parallelogram shape. The first-second sensor pattern area RA-L2 may be further away from the first pad area PA-PX than the first-first sensor pattern area RA-L1 and may be shifted in an oblique direction with respect to each of the first and second directions DR1 and DR2.

The display panel 100-B may include a second-first sensor connection lines SC-R1 connected to some of the lead-out lines located at the right side of the active area AA with respect to the central axis CX and a second-second sensor connection lines SC-R2 connected to other lead-out lines.

Each of the second-first sensor connection lines SC-R1 and second-second sensor connection lines SC-R2 may include a first sensor pattern extending in the first direction DR1 and a second sensor pattern connected to the first sensor pattern and extending in the second direction DR2. An area on which the second sensor patterns included in the second-first sensor connection lines SC-R1 are located may be defined as the second-first sensor pattern area RA-R1, and an area on which the second sensor patterns included in the second-second sensor connection lines SC-R2 are located may be defined as a second-second sensor pattern area RA-R2.

According to some embodiments, each of the second-first sensor pattern area RA-R1 and the second-second sensor pattern area RA-R2 may have a parallelogram shape. The second-second sensor pattern area RA-R2 may be further away from the first pad area PA-PX than the second-first sensor pattern area RA-R1 and may be shifted in an oblique direction with respect to each of the first and second directions DR1 and DR2.

However, the embodiments of the present disclosure are not limited thereto, and at least one of the first-first sensor pattern area RA-L1, the first-second sensor pattern area RA-L2, the second-first sensor pattern area RA-R1, or the second-second sensor pattern area RA-R2 may have a triangular shape or an inverted triangular shape.

According to some embodiments, a mesh structure MST may be located between the first-first sensor pattern area RA-L1 and the second-first sensor pattern area RA-R1. An area on which the mesh structure MST is located between the first-first sensor pattern area RA-L1 and the second-first sensor pattern area RA-R1 may be defined as a first sensor dummy area DM-R1. Widths of the second mesh lines M2 located on the first sensor dummy area DM-R1 in the second direction DR2 may be the same as each other.

A mesh structure MST may be located between the first-second sensor pattern area RA-L2 and the second-second sensor pattern area RA-R2. An area on which the mesh structure MST is located between the first-second sensor pattern area RA-L2 and the second-second sensor pattern area RA-R2 may be defined as a second sensor dummy area DM-R2. Widths of the second mesh lines M2 located on the second sensor dummy area DM-R2 in the second direction DR2 may be the same as each other.

Referring to FIG. 14, a display panel 100-E according to some embodiments may include first-first pixel connection lines PC-L1 connected to some of the data lines located at the left side of the active area AA, first-second pixel connection lines PC-L2 connected to other data lines, and first-third pixel connection lines PC-L3 connected to other data lines.

Each of the first-first pixel connection lines PC-L1, the first-second pixel connection lines PC-L2, and the first-third pixel connection lines PC-L3 may include a first pixel pattern and a second pixel pattern connected to a corresponding first pixel pattern. Each of the first pixel patterns may extend in the first direction DR1 and may be located between corresponding data lines of the data lines. Each of the second pixel patterns may extend in the second direction DR2.

An area on which the second pixel patterns included in the first-first pixel connection lines PC-L1 are located may be defined as the first-first pixel pattern area DA-L1, an area on which the second pixel patterns included in the first-second pixel connection lines PC-L2 are located may be defined as a first-second pixel pattern area DA-L2, and an area on which the second pixel patterns included in the first-third pixel connection lines PC-L3 are located may be defined as a first-third pixel pattern area DA-L3.

The display panel 100-E may include second-first pixel connection lines PC-R1 connected to some of the data lines located at the right side of the active area AA with respect to the central axis CX, second-second pixel connection lines PC-R2 connected to other data lines, and second-third pixel connection lines PC-R3 connected to other data lines.

Each of the second-first pixel connection lines PC-R1, the second-second pixel connection lines PC-R2, and the second-third pixel connection lines PC-R3 may include a first pixel pattern and a second pixel pattern connected to a corresponding first pixel pattern. Each of the first pixel patterns may extend in the first direction DR1 and may be located between corresponding data lines of the data lines. Each of the second pixel patterns may extend in the second direction DR2.

An area on which the second pixel patterns included in the second-first pixel connection lines PC-R1 are located may be defined as the second-first pixel pattern area DA-R1, an area on which the second pixel patterns included in the second-second pixel connection lines PC-R2 are located may be defined as a second-second pixel pattern area DA-R2, and an area on which the second pixel patterns included in the second-third pixel connection lines PC-R3 are located may be defined as a second-third pixel pattern area DA-R3.

According to some embodiments, each of the first-first pixel pattern area DA-L1, the first-second pixel pattern area DA-L2, the first-third pixel pattern area DA-L3, the second-first pixel pattern area DA-R1, the second-second pixel pattern area DA-R2, and the second-second pixel pattern area DA-R2 may have an inverted triangular shape on the plane (or in a plan view).

In addition, the first-first pixel pattern area DA-L1 and the second-first pixel pattern area DA-R1 may have symmetrical shapes with respect to the center layer CX, and the first-second pixel pattern area DA-L2 and the second-second pixel pattern area DA-R2 may have symmetrical shapes with respect to the center layer CX, and the first-third pixel pattern area DA-L3 and the second-third pixel pattern area DA-R3 may be symmetrical to each other with respect to the central axis CX.

An area on which the mesh structure MST is located between the first-first pixel pattern area DA-L1 and the second-first pixel pattern area DA-R1 may be defined as a central pixel dummy area DM-C, an area on which the mesh structure MST is located between the first-first pixel pattern area DA-L1 and the first-second pixel pattern area DA-L2 may be defined as a first-first pixel dummy area DM-L1, and an area on which the mesh structure MST is located between the first-second pixel pattern area DA-L2 and the first-third pixel pattern area DA-L3 may be defined as a first-second pixel dummy area DM-L2.

An area on which the mesh structure MST is located between the second-first pixel pattern area DA-R1 and the second-second pixel pattern area DA-R2 may be defined as the second-first pixel dummy area DM-R1, and an area on which the mesh structure MST is located between the second-second pixel pattern area DA-R2 and the second-third pixel pattern area DA-R3 may be defined as a second-second pixel dummy area DM-R2.

Each of the dummy areas DM-C, DM-L1, DM-L2, DM-R1, and DM-R2 may have a triangular shape on the plane (or in a plan view).

The display panel 100-E may include first-first sensor connection lines SC-L1 connected to some of the lead-out lines located at the left side of the active area AA with respect to the central axis CX, first-second sensor connection lines SC-L2 connected to other lead-out lines, and first-third sensor connection lines SC-L3 connected to other lead-out lines.

Each of the first-first sensor connection lines SC-L1, the first-second sensor connection lines SC-L2, and first-third sensor connection lines SC-L3 may include a first sensor pattern extending in the first direction DR1 and a second sensor pattern connected to the first sensor pattern and extending in the second direction DR2. An area on which the second sensor patterns included in the first-first sensor connection lines SC-L1 are located may be defined as the first-first sensor pattern area RA-L1, an area on which the second sensor patterns included in the first-second sensor connection lines SC-L2 are located may be defined as a first-second sensor pattern area RA-L2, and an area on which the second sensor patterns included in the first-third sensor connection lines SC-L3 are located may be defined as a first-third sensor pattern area RA-L3.

According to some embodiments, each of the first-first sensor pattern area RA-L1, the first-second sensor pattern area RA-L2, and the first-third sensor pattern area RA-L3 may have a parallelogram shape. The first-second sensor pattern area RA-L2 may be further away from the first pad area PA-PX than the first-first sensor pattern area RA-L1 and may be shifted in an oblique direction with respect to each of the first and second directions DR1 and DR2.

The first-third sensor pattern area RA-L3 may be further away from the first pad area PA-PX than the first-second sensor pattern area RA-L2 and be shifted in an oblique direction.

The display panel 100-E may include second-first sensor connection lines SC-R1 connected to some of the lead-out lines located at the right side of the active area AA with respect to the central axis CX, second-second sensor connection lines SC-R2 connected to other lead-out lines, and second-third sensor connection lines SC-R3 connected to other lead-out lines.

Each of the second-first sensor connection lines SC-R1, the second-second sensor connection lines SC-R2, and second-third sensor connection lines SC-R3 may include a first sensor pattern extending in the first direction DR1 and a second sensor pattern connected to the first sensor pattern and extending in the second direction DR2. An area on which the second sensor patterns included in the second-first sensor connection lines SC-R1 are located may be defined as the second-first sensor pattern area RA-R1, an area on which the second sensor patterns included in the second-second sensor connection lines SC-R2 are located may be defined as a second-second sensor pattern area RA-R2, and an area on which the second sensor patterns included in the second-third sensor connection lines SC-R3 are located may be defined as a second-third sensor pattern area RA-R3.

According to some embodiments, each of the second-first sensor pattern area RA-R1, the second-second sensor pattern area RA-R2, and the second-third sensor pattern area RA-R3 may have a parallelogram shape. The second-second sensor pattern area RA-R2 may be further away from the first pad area PA-PX than the second-first sensor pattern area RA-R1 and may be shifted in an oblique direction with respect to each of the first and second directions DR1 and DR2.

The second-third sensor pattern area RA-R3 may be further away from the first pad area PA-PX than the second-second sensor pattern area RA-R2 and be shifted in an oblique direction.

However, the embodiments of the present disclosure are not limited thereto, and at least one of the first-first sensor pattern area RA-L1, the first-second sensor pattern area RA-L2, the first-third sensor pattern area RA-L3, the second-first sensor pattern area RA-R1, the second-second sensor pattern area RA-R2, or the second-third sensor pattern area RA-R3 may have a triangular shape or an inverted triangular shape.

According to some embodiments, a mesh structure MST may be located between the first-first sensor pattern area RA-L1 and the second-first sensor pattern area RA-R1. An area on which the mesh structure MST is located between the first-first sensor pattern area RA-L1 and the second-first sensor pattern area RA-R1 may be defined as a first sensor dummy area DM-R1. Widths of the second mesh lines M2 located on the first sensor dummy area DM-R1 in the second direction DR2 may be the same as each other.

A mesh structure MST may be located between the first-second sensor pattern area RA-L2 and the second-second sensor pattern area RA-R2. An area on which the mesh structure MST is located between the first-second sensor pattern area RA-L2 and the second-second sensor pattern area RA-R2 may be defined as a second sensor dummy area DM-R2. Widths of the second mesh lines M2 located on the second sensor dummy area DM-R2 in the second direction DR2 may be the same as each other.

A mesh structure MST may be located between the first-third sensor pattern area RA-L3 and the second-third sensor pattern area RA-R3. An area on which the mesh structure MST is located between the first-third sensor pattern area RA-L3 and the second-third sensor pattern area RA-R3 may be defined as a third sensor dummy area DM-R3. Widths of the second mesh lines M2 located on the third sensor dummy area DM-R3 in the second direction DR2 may be the same as each other.

The display panel according to some embodiments of the present disclosure may prevent or reduce instances of the resistance increasing due to a bottleneck phenomenon of the driving voltage in the active area.

It will be apparent to those skilled in the art that various modifications and deviations can be made in the present disclosure. Thus, it is intended that the present disclosure covers the modifications and deviations of this invention provided they come within the scope of the appended claims and their equivalents.

Accordingly, the technical scope of the present disclosure should not be limited to the contents described in the detailed description of the specification, but should be determined by the appended claims and their equivalents.

What is claimed is:

1. A display panel comprising:
a base layer comprising an active area and a peripheral area adjacent to the active area;
data lines extending in a first direction, arranged in a second direction crossing the first direction, and on the base layer;
pixels which are connected to the corresponding data lines and each of which comprises an emission layer;
lead-out lines extending in the first direction and located between the data lines adjacent to each other on the base layer;
sensors which are connected to the corresponding lead-out lines, each of which comprises a photoelectric conversion layer, and are between adjacent pixels from among the pixels; and
sensor connection lines comprising first lead-out connection lines at a first side of the base layer and second lead-out connection lines at a second side of the base layer based on a central axis extending in the first direction to cross a center of the base layer, the sensor connection line being connected to the corresponding lead-out lines,
wherein each of the first lead-out connection lines and the second lead-out connection lines comprises a first sensor pattern extending in the first direction and a second sensor pattern extending in the second direction to cross one of the data lines and the lead-out lines in a plan view.

2. The display panel of claim 1, further comprising a mesh structure overlapping the active area and comprising first mesh lines extending in the first direction respectively and second mesh lines on a layer which is different from a layer on which the first mesh lines are located, and configured to define mesh openings, each of which surrounds the emission layer and the photoelectric conversion layer in the plan view,
wherein the first mesh lines are on a same layer as the first sensor patterns and spaced apart from the data lines, the lead-out lines, and the first sensor patterns, and
the second mesh lines are on a same layer as the second sensor patterns and spaced apart from the second sensor patterns.

3. The display panel of claim 2, wherein a first side of each of the second sensor patterns is connected to the corresponding lead-out line, and a second side opposite to the first side in the second direction is connected to the corresponding first sensor pattern.

4. The display panel of claim 3, wherein the second sensor patterns have a same width in the second direction,
an area on which the second sensor patterns included in the first lead-out connection lines are located has a first trapezoidal shape in the plan view, and
an area on which the second sensor patterns included in the second lead-out connection lines are located has a second trapezoidal shape in the plan view.

5. The display panel of claim 4, wherein the first trapezoidal shape and the second trapezoidal shape are symmetrical to each other with respect to the central axis.

6. The display panel of claim 4, wherein the second trapezoidal shape is shifted in the first direction compared to the first trapezoidal shape.

7. The display panel of claim 4, wherein the second sensor patterns of the first lead-out connection lines aligned with each other in the second direction and the second mesh lines between the second sensor patterns of second lead-out lines have a same width in the second direction.

8. The display panel of claim 4, wherein widths of the second sensor patterns of first sensor connection patterns aligned with each other in the second direction and the second mesh lines between the second sensor patterns of second sensor connection patterns in the second direction is more than 5% of a width of the active area in the second direction.

9. The display panel of claim 3, wherein widths of the second sensor patterns in the second direction gradually increase from a bottom to a top of the active area,
an area on which the second sensor patterns included in the first lead-out connection lines are located has a first inverted triangular shape in the plan view, and
an area on which the second sensor patterns included in the second lead-out connection lines are located has a second inverted triangular shape in the plan view.

10. The display panel of claim 9, wherein the second inverted triangular shape is shifted in the first direction compared to the first inverted triangular shape.

11. The display panel of claim 2, further comprising a signal line along a boundary between the active area and the peripheral area and connected to the mesh structure.

12. The display panel of claim 11, wherein the signal line is configured to receive at least one of a driving voltage, an initialization voltage, or a reset voltage.

13. The display panel of claim 2, further comprising a data connection line comprising first pixel connection lines at the first side of the base layer and second pixel connection lines at the second side of the base layer with respect to the central axis, the data connection line being connected to the corresponding data lines,
wherein each of the first pixel connection lines and the second pixel connection lines comprises a first pixel pattern extending in the first direction and a second pixel pattern extending in the second direction to cross one of the data lines and the lead-out lines in the plan view.

14. The display panel of claim 13, wherein the mesh structure is spaced apart from the data connection line.

15. The display panel of claim 13, wherein widths of the second pixel patterns in the second direction gradually increase from bottom to top of the active area,
an area on which the second pixel patterns included in the first pixel connection lines are located has a third inverted triangular shape in the plan view, and
an area on which the second pixel patterns included in the second pixel connection lines are located has a fourth inverted triangular shape in the plan view.

16. The display panel of claim 15, wherein the third inverted triangular shape and the fourth inverted triangular shape are symmetrical to each other with respect to the central axis.

17. The display panel of claim 13, wherein second sensor lines, second pixel lines, and the second mesh lines are on a same layer.

18. The display panel of claim 13, wherein a portion of each of the lead-out lines, the data lines, a first sensor line, first pixel lines, and the first mesh lines are on a same layer.

19. The display panel of claim 13, further comprising a first pad part connected to the pixels and second pad parts connected to the sensors and spaced apart from each other in the second direction with the first pad part therebetween,
wherein data lines connected to the data connection line among the data lines are connected to the first pad part through the corresponding first pixel patterns, and remaining data lines are directly connected to the first pad part, and
lead-out lines connected to a sensor connection line among the lead-out lines are connected to the corresponding second pad part through the first sensor patterns, and remaining lead-out lines are directly connected to the corresponding second pad part.

20. The display panel of claim 1, wherein each of the pixels comprises a first electrode below the emission layer, a first functional layer between the first electrode and the emission layer, a second electrode on the emission layer, and a second functional layer between the second electrode and the emission layer, and
each of the sensors comprises a first electrode below the photoelectric conversion layer, a first functional layer between the first electrode and the photoelectric conversion layer, a second electrode on the photoelectric conversion layer, and a second functional layer between the second electrode and the photoelectric conversion layer,
wherein the first functional layer, the second functional layer, and the second electrode, which are included in each of the pixels and the sensors, are provided as common layers.
